(19) United States
(12) Patent Application Publication
(10) Pub. No.: US 2025/0116710 A1
(43) Pub. Date: Apr. 10, 2025

(54) BATTERY MONITORING SYSTEM, BATTERY MONITORING APPARATUS, AND BATTERY CONTROLLER

(71) Applicant: DENSO CORPORATION, Kariya-city (JP)

(72) Inventors: Yuto HONDA, Kariya-city (JP); Sho MATSUMOTO, Kariya-city (JP); Ryu ATSUTA, Kariya-city (JP); Tomohisa KISHIGAMI, Kariya-city (JP); Youichi HAYASE, Kariya-city (JP); Kohki OHBA, Kariya-city (JP)

(73) Assignee: DENSO CORPORATION, Kariya-city (JP)

(21) Appl. No.: 18/983,994

(22) Filed: Dec. 17, 2024

Related U.S. Application Data
(63) Continuation of application No. PCT/JP2023/020526, filed on Jun. 1, 2023.

(30) Foreign Application Priority Data
Jun. 17, 2022 (JP) 2022-098018

(51) Int. Cl. G01R 31/371; B60L 58/12; B60L 58/16; B60L 58/18; G01R 31/382

(52) U.S. Cl. CPC G01R 31/371; B60L 58/18; G01R 31/382; B60L 58/12; B60L 58/16

(57) ABSTRACT

A battery controller is equipped with a primary antenna used in radio communication between itself and battery monitors. Each of the battery monitors is equipped with a secondary antenna used in radio communication between itself and the battery controller. Each of the secondary antennas and/or the primary antenna is configured to selectively have a first antenna directivity that is one of a plurality of directivities whose center axes are different in orientation from each other. The first antenna directivity excludes one of the directivities which causes a degree of quality of radio communication between the primary antenna and a corresponding one of the secondary antennas to be minimized or the lowest among the directivities on a channel used for the radio communication.

### CROSS REFERENCE TO RELATED DOCUMENT

The present application claims the benefit of priority of Japanese Patent Application No. 2022-098018 filed on Jun. 17, 2022, the disclosure of which is incorporated in its entirety herein by reference.

### TECHNICAL FIELD

This disclosure relates generally to a battery monitoring system, a battery monitoring apparatus constituting a battery monitoring system, and a battery controller constituting a battery monitoring system.

### BACKGROUND ART

Battery monitoring systems are known which include battery monitors provided one for each of a plurality of batteries and a battery controller. The battery controller is equipped with a primary antenna used to wirelessly communicate with each of the battery monitors. Each of the battery monitors is equipped with a secondary antenna used to wirelessly communicate with the battery controller.

The batteries, the battery monitors, and the battery controller are disposed within a storage chamber. The storage chamber is configured to have at least a portion which reflects a radio wave thereon. This causes a radio signal outputted from each of the battery monitors to be reflected on a wall surface of the storage chamber, thereby resulting in multipath which will lead to a difficulty in transmitting proper information from the battery monitors to the battery controller.

In order to alleviate the above problem, the first patent literature listed below teaches a structure in which the primary antenna and/or each of the secondary antennas is made of a directional antenna which works to radiate greater radio wave power in a specific direction than non-directional antennas. The directional antenna disclosed in the first patent literature is oriented to emit a radio wave in a direction parallel to a surface of each of the batteries on which the battery controller or a corresponding one of the battery monitors is mounted to have power greater than in a direction perpendicular to the above surface of each of the batteries. This enables the directivity of the directional antenna to be suitable for ensuring a required condition of radio communication between the battery controller and each of the battery monitors in the storage chamber to achieve transmission of proper information from the battery monitors to the battery controller.

### PRIOR ART DOCUMENT

### Patent Literature

FIRST PATENT LITERATURE: Japanese Patent No. 6996574

### SUMMARY OF THE INVENTION

The storage chamber may be subjected to a change in condition of radio communication between the battery controller and each of the battery monitors, which will lead to a risk that information may be transmitted incorrectly between each of the battery monitors and the battery controller.

It is, therefore, an object of this disclosure to provide a battery monitoring system, a battery monitor installed in the battery monitoring system, and a battery controller installed in the battery monitoring system which are capable of ensuring the stability in achieving a required quality of radio communication between the battery controller and the battery monitor.

According to one aspect of this disclosure, there is provided a battery monitoring system which comprises: (a) battery monitors which are provided one for each of a plurality of batteries and work to monitor states of the batteries; (b) a battery controller; and (c) a storage chamber which has at least a portion configured to reflect a radio wave thereon and in which the batteries, the battery monitors, and the battery controller are arranged. The battery controller includes a primary antenna used in radio communications with the battery monitors. Each of the battery monitors includes a secondary antenna used in radio communication with the battery controller. Each of the secondary antennas and/or the primary antenna is configured to selectively have a first antenna directivity that is one of a plurality of directivities whose center axes are different in orientation from each other. The first antenna directivity excludes one of the directivities which causes a degree of quality of radio communication between the primary antenna and a corresponding one of the secondary antennas to be the lowest among the directivities on a channel used for the radio communication.

The changing of the antenna directivity ensures the stability in transmitting proper information between each of the battery monitor and the battery controller regardless of an undesirable change in condition of the radio transmission.

In view of the above, each of the secondary antennas and/or the primary antenna is designed to selectively have the first antenna directivity that is one of the plurality of directivities whose center axes are different in orientation from each other. Further, the first antenna directivity excludes one of the directivities which causes a degree of quality of radio communication between the primary antenna and a corresponding one of the secondary antennas to be minimized or the lowest among the directivities on a channel used for the radio communication. This enables the radio communication between the battery controller and each of the battery monitors to be achieved properly regardless of a change in condition of the radio communication.

For instance, the first antenna directivity is set to one of the directivities which causes an amount of power received by each of the battery monitors or the battery controller in the radio communication to be higher than or equal to a given threshold.

### BRIEF DESCRIPTION OF THE DRAWINGS

The above-described object, other objects, features, or beneficial advantages in this disclosure will be apparent from the following detailed discussion with reference to the drawings.

In the drawings:

FIG. 1 is a structural view of a vehicle according to the first embodiment;

FIG. 2 is a block diagram which illustrates a battery pack;

FIG. 3 is a perspective view which illustrates a layout of a battery block in a housing;

FIG. 4 is a cross-sectional view taken along the line 4-4 in FIG. 3;

FIGS. 5A and 5B are views which illustrate a layout of electrical cells of a battery block;

FIG. 6 is a perspective view which illustrates a structure capable of switching between two antenna directivities;

FIG. 7 is a view which represents a frequency response of received power for directivities A and B;

FIG. 8 is a view which demonstrates interference between a dominant wave and a reflected wave;

FIGS. 9A and 9B are time charts which represent changes in dominant wave, reflected wave, and mixture of the dominant wave and the reflected wave;

FIG. 10 is a view which represents a correspondence relation of an antenna directivity which maximizes received power and each channel;

FIG. 11 is a flowchart of a sequence of steps to generate map information about a linkage between an antenna directivity which maximizes received power and each channel;

FIG. 12 is a flowchart of a sequence of steps of an antenna directivity switching task performed by each battery monitor;

FIGS. 13A and 13B are views which demonstrate examples of antennas capable of changing a directivity thereof;

FIG. 14 is a view which demonstrates an example of an antenna capable of changing a directivity thereof;

FIGS. 15A and 15B are views which demonstrate examples of antennas capable of changing a directivity thereof;

FIG. 16 is a view which illustrates a comparative example of an antenna;

FIG. 17 is a view which illustrates a modification of a structure shown in FIGS. 15A-15B;

FIG. 18 a view which illustrates reuse of a battery from a vehicle-mounted application to a stationary mounted application;

FIG. 19 is a view which represents a frequency response of received power in a vehicle-mounted application;

FIG. 20 is a view which represents a frequency response of received power in a stationary mounted application;

FIG. 21 is a view which represents a frequency response of received power when an antenna directivity on each channel is switched in a stationary mounted application;

FIG. 22 is a view which represents a frequency response of received power before an antenna directivity is changed;

FIG. 23 is a view which represents a frequency response of received power after an antenna directivity is changed;

FIG. 24 is a flowchart of a sequence of steps of an antenna directivity switching task performed when a malfunction occurs;

FIG. 25 is a perspective view which illustrates a layout of battery blocks within a housing in a modified form of the first embodiment;

FIG. 26 is a flowchart of a sequence of steps to generate map information about a linkage between an antenna directivity which maximizes received power and each channel according to the second embodiment;

FIG. 27 is a flowchart of a sequence of steps of an antenna directivity switching task performed by a battery controller according to the second embodiment;

FIG. 28 is a view which illustrates an overall structure of an inspection system equipped with a mobile device and a server according to the third embodiment;

FIG. 29 is a flowchart of a sequence of steps to generate map information about a linkage between an antenna directivity which maximizes received power and each channel according to the second embodiment;

FIG. 30 is a flowchart of a sequence of steps to generate map information about a linkage between an antenna directivity which maximizes received power and each channel according to the fourth embodiment;

FIG. 31 is a view which demonstrates an example of a specific condition;

FIG. 32 is a flowchart of a sequence of steps to generate map information about a linkage between an antenna directivity which maximizes received power and each channel according to the fifth embodiment;

FIG. 33 is a perspective view which illustrates a layout of battery blocks within a housing upon occurrence of a malfunction according to the sixth embodiment;

FIG. 34 is a flowchart of a sequence of steps to generate map information about a linkage between an antenna directivity which maximizes received power and each channel according to the sixth embodiment;

FIG. 35 is a graph which represents a relation among each channel, a communication error rate, and an antenna directivity in the seventh embodiment;

FIG. 36 is a flowchart of a sequence of steps to generate map information about a linkage between an antenna directivity which minimizes a communication error rate and each channel according to the seventh embodiment;

FIG. 37 is a graph which represents a relation between each channel and a difference between an amount of received power and a noise floor for an antenna directivity A according to the eighth embodiment;

FIG. 38 is a graph which represents a relation between each channel and a difference between an amount of received power and a noise floor for an antenna directivity B according to the eighth embodiment;

FIG. 39 is a flowchart of a sequence of steps to generate map information about a linkage of an antenna directivity which maximizes a difference between an amount of received power and a noise floor with each channel according to the eighth embodiment;

FIG. 40 is a view which illustrates a layout of a battery pack in a storage chamber formed inside a chassis of a vehicle according to the ninth embodiment;

FIG. 41 is a longitudinal cross-sectional view taken along the line 41-41 in FIG. 40;

FIG. 42 is a cross-sectional view of a battery pack according to the tenth embodiment;

FIG. 43 is a cross-sectional view of a battery pack according to the eleventh embodiment;

FIG. 44 is a side view which illustrate a layout of batteries in a storage chamber formed inside a chassis of a vehicle according to the twelfth embodiment; and

FIG. 45 is a perspective view which illustrates batteries according to another embodiment.

### MODE FOR CARRYING OUT THE INVENTION

Embodiments will be described below with reference to the drawings through which functional or structural elements identical in the embodiments or corresponding elements in the embodiments will be denoted by the same or similar reference numbers or symbols, and explanation thereof in the embodiments refer to each other.

### First Embodiment

A battery monitoring system according to the first embodiment will be described below with reference to the drawings. The battery monitoring system is installed in an electrical vehicle or a hybrid vehicle driven by a traction power source, such as a rotating electrical machine.

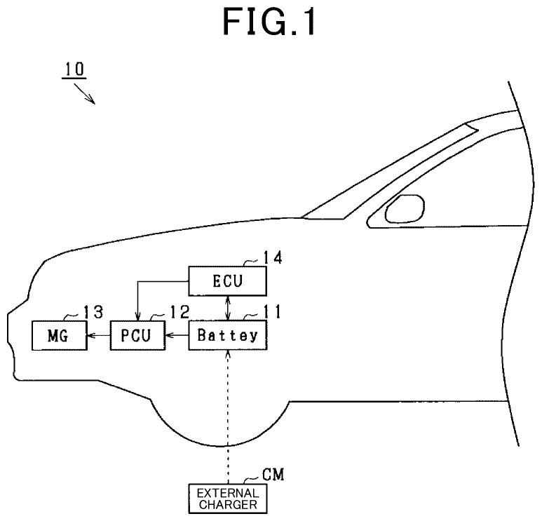

FIG. 1 is a view which schematically illustrates a structure of the vehicle 10. The vehicle 10 is equipped with the battery pack 11, the power control unit 12 (which will also be referred to as the PCU 12), the motor 13, and the vehicle ECU 14.

The battery pack 11 is installed in the vehicle 10 and used as an electrical drive source for driving the vehicle 10. Specifically, the battery pack 11 is mounted in an engine compartment or a trunk of the vehicle 10 or arranged below a seat or a floor of the vehicle 10. The vehicle 10 is moved using an electrical power stored in the battery pack 11.

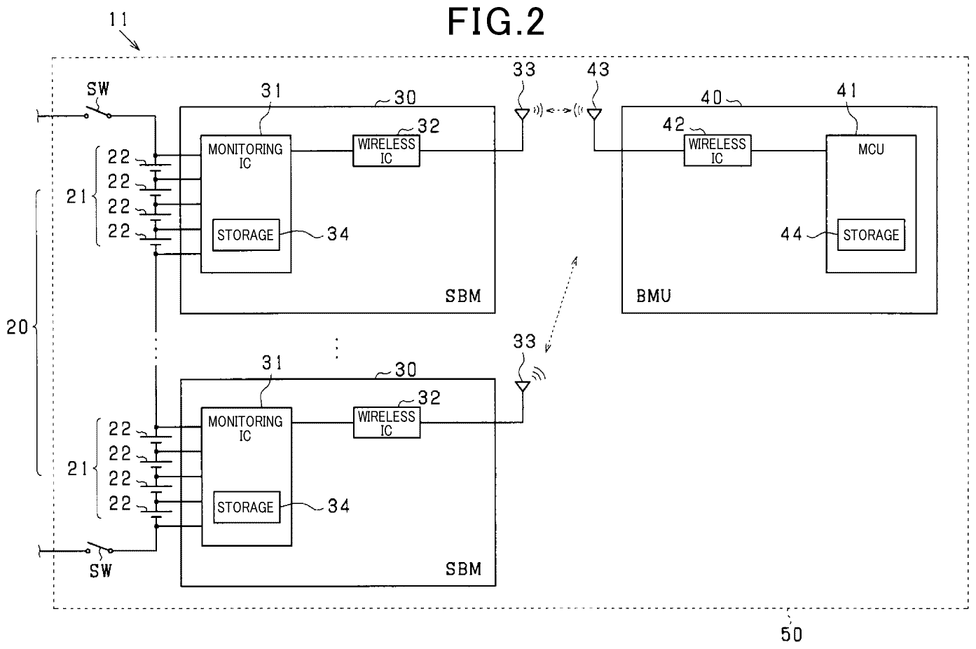

The battery pack 11, as clearly illustrated in FIG. 2, includes the assembled battery 20 made up of a plurality of electrical cells 22 (i.e., secondary cells which will also be simply referred to as batteries) which are electrically connected in series with each other. The assembled battery 20 stores therein electrical power used to drive the motor 13 and is capable of supplying the electrical power to the motor 13 through the PCU 12. When the motor 13 is in a regenerative mode during braking of the vehicle 10, the assembled battery 20 is supplied with electrical power from the motor 13, so that it is electrically charged. The assembled battery 20 is, as illustrated in FIG. 1, connectable with the external battery charger CM arranged outside the vehicle 10. The external battery charger CM is a stationary electrically charger and works to electrically charge the assembled battery 20.

The PCU 12 is responsive to a control signal outputted from the vehicle ECU 14 to convert electrical energy from the battery pack 11 to the motor 13, and vice versa. For instance, the PCU 12 includes an inverter and a converter. The inverter functions to operate the motor 13. The converter functions to step-up dc voltage, as delivered to the inverter, to be higher than or equal to an output voltage at the battery pack 11.

The motor 13 is implemented by an ac rotating electrical machine. For instance, the motor 13 is made of an ac three-phase synchronous motor designed to have permanent magnets embedded in a rotor thereof. The motor 13 is driven by the PCU 12 to generate rotational force or torque which is then delivered to drive wheels of the vehicle 10. When the vehicle 10 is being braked, the motor 13 works as a generator to produce regenerative energy. The electrical power regenerated by the motor 13 is supplied to the battery pack 11 through the PCU 12, so that it is stored in the assembled battery 20 of the battery pack 11.

The vehicle ECU 14 includes a CPU, a ROM, a RAM, and input-output ports through which various types of signals are inputted to or outputted from the vehicle ECU 14. The CPU works to read programs out of the ROM and implements the programs in the RAM. The programs stored in the ROM provide tasks to be performed by the vehicle ECU 14. In one example of a major one of the tasks, the vehicle ECU 14 receives, from the battery pack 11, information about voltage at, electrical current from, an SOC (Sate Of Charge), and an SOH (State Of Health) of the assembled battery 20 and then controls operation of the PCU 12 to control operation of the motor 13 and charging or discharging operation of the battery pack 11.

FIG. 2 is a block diagram which schematically illustrates the structure of the battery pack 11. The battery pack 11 includes the assembled battery 20, a plurality of battery monitors 30, the battery controller 40, and the housing 50 in which the assembled battery 20, the battery monitors 30, and the battery controller 40 are stored. The battery pack 20 plays a role as a battery monitoring system in this embodiment.

The assembled battery 20 includes a plurality of battery blocks 21 (which will also be simply referred to as batteries) which are electrically connected in series with each other. Each of the battery blocks 21 is also referred to as a battery stack or a battery module. Each of the battery blocks 21 includes a plurality of electrical cells 22. Each of the electrical cells 22 is made of a lithium-ion secondary cell or a nickel hydride cell. The lithium-ion secondary cell is a secondary cell which uses lithium as a charge carrier, e.g., a typical lithium-ion secondary cell in which uses liquid electrolyte or an all solid state battery which uses a solid electrolyte. The assembled battery 20 may be designed to have a plurality of battery units which are electrically connected in parallel to each other and each of which includes the battery blocks 21 electrically connected in series with each other. The assembled battery 20 electrically connects with the PCU 12 using switches SW (e.g., relays) and the electrical conductors 16.

Each of the battery monitors 30 is referred to as a satellite battery module (SBM) and provided for a respective one of the battery blocks 21. Each of the battery monitors 30, as illustrated in FIG. 2, includes the monitoring integrated circuit 31 working as a monitor, the secondary wireless integrated circuit 32 working as a wireless controller, and the secondary antenna 33 working as a wireless antenna. The secondary wireless integrated circuit 32 and the secondary antenna 33 installed in each of the battery monitors 30 work as a secondary communication device to achieve communication with the battery controller 40. The monitoring integrated circuit 31 is generally referred to as a cell supervising circuit (CSC) and works to obtain battery information from each of the electrical cells 22 of a corresponding one of the battery blocks 21 or sensors (not shown). The battery information represents, for example, a voltage developed at, a temperature of, and an electrical current from a corresponding one of the electrical cells 22. The monitoring integrated circuit 31 performs self-diagnosis and produce self-diagnostic information which includes information about a check of an operation of a corresponding one of the battery monitors 30, i.e., a malfunction or failure in operation of a corresponding one of the battery monitors 30. Specifically, the self-diagnostic information represents a state of operation of the monitoring integrated circuit 31 and/or the secondary wireless integrated circuit 32 of a corresponding one of the battery monitors 30.

The secondary wireless integrated circuit 32 is connected to the monitoring integrated circuit 31 through a wired connection and includes a wireless MCU (i.e., a Micro Control Unit) and an RF device (i.e., a high-frequency device module). The secondary wireless integrated circuit 32 receives data from the monitoring integrated circuit 31 and outputs it through the secondary antenna 33 in a wireless mode. The secondary wireless integrated circuit 32 also receives data through the secondary antenna 33 and then delivers it to the monitoring integrated circuit 31.

The monitoring integrated circuit 31 is equipped with the secondary storage device 34. The secondary storage device 34 is made of a non-volatile memory other than a ROM, e.g., a non-transitory tangible storage medium. The monitoring integrated circuit 31 obtains the batter information and the self-diagnostic information and stores them in the secondary storage device 34.

The battery controller 40 is generally referred to as a battery ECU or a BMU (Battery Management Unit). The battery controller 40 is communicable with each of the battery monitors 30 in a wireless mode. Specifically, the battery controller 40 includes the micro controller unit 41 working as a battery controller, the primary wireless integrated circuit 42 working as a wireless controller, the primary wireless integrated circuit 42 working as a wireless controller, and the primary antenna 43 working as a wireless antenna. The primary wireless integrated circuit 42 and the primary antenna 43 serve as a primary communication device to achieve communication with the battery monitors 30. The micro controller unit 41 is made of a microcomputer including a CPU, a ROM, a RAM, and an input-output interface. The CPU of the micro controller unit 41 works to read programs out of the ROM and implement them in the RAM. The programs stored in the ROM provide battery control tasks.

In an example of a major one of the battery control tasks, the micro controller unit 41 instructs each of the battery monitors 30 to obtain the batter information and output it. The micro controller unit 41 analyzes the battery information received from each of the battery monitors 30 to supervise the assembled battery 20, the battery blocks 21, and the electrical cells 22. The micro controller unit 41 also analyzes results of the supervision to control operations of the switches SW to energize or deenergize the assembled battery 20, the PCU 12, and the motor 13. The micro controller unit 41 outputs an equalization signal to equalize voltages developed at the electrical cells 22 as needed.

The primary wireless integrated circuit 42 is connected to the micro controller unit 41 through a wired connection and, like the secondary wireless integrated circuit 32, includes a wireless MCU (i.e., a Micro Control Unit) and an RF device (i.e., a high-frequency device module). The primary wireless integrated circuit 42 receives data from the micro controller unit 41 and then outputs it through the primary antenna 43 in a wireless mode. The primary wireless integrated circuit 42 also receives data using the primary antenna 43 and then transmits it to the micro controller unit 41. Each of the primary antenna 43 and the secondary antenna 33 may be implemented by a dipole antenna, a Yagi antenna, a slot antenna, an inverted-F antenna, an inverted-L antenna, a chip antenna, or a zero-order antenna (e.g., a zero-order resonator antenna).

The micro controller unit 41 includes the primary storage device 44. The primary storage device 44 is made of a non-transitory tangible storage medium (i.e., a non-volatile memory other than a ROM).

The assembled battery 20, the battery monitors 30, the battery controller 40, and the housing 50 in which the assembled battery 20, the battery monitors 30, and the battery controller 40 are disposed constitute a battery monitoring system.

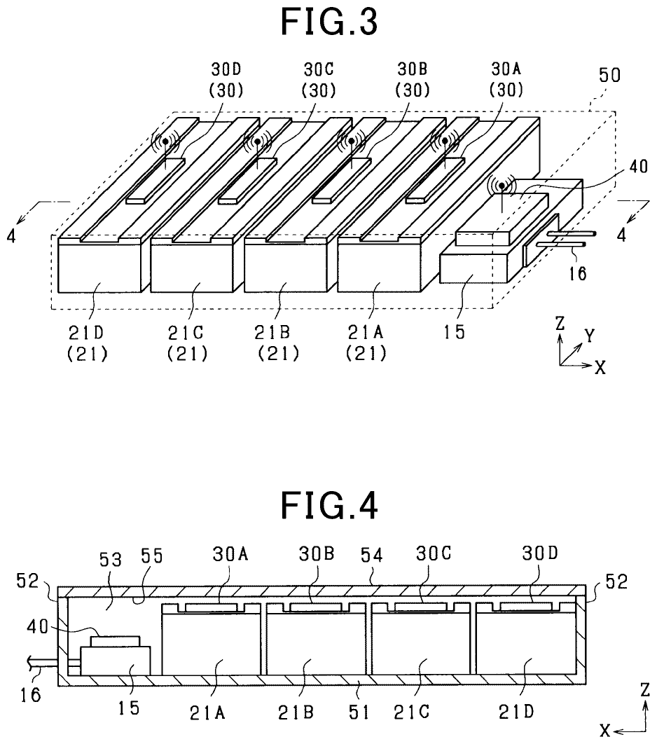

The layout of the housing 50 and the battery blocks 21 arranged inside the housing 50 will be described below with reference to FIGS. 3 and 4. FIG. 4 is a sectional view taken along the line 4-4 in FIG. 3. For the sake of convenience, hatching is omitted from portions of the structure illustrated in FIG. 4.

The housing 50 includes the bottom plate 51 and a side wall extending along a peripheral edge of the bottom plate 51. The bottom plate 51 is of a rectangular shape. The side wall includes a pair of first walls 52 extending along shorter sides of the bottom plate 51 and a pair of second walls 53 extending along longer sides of the bottom plate 51.

The housing 50 also includes the cover 54. The cover 54 is arranged on upper ends of the first walls 52 and the second walls 53. The cover 54 is removable from a base of the housing 50 which is made up of the bottom plate 51 and the side wall. The cover 54 is secured to the base of the housing 50 using fasteners, such as bolts. The bottom plate 51, the first walls 52, the second walls 53, and the cover 54 have inner surfaces defining the storage chamber 55. The storage chamber 55 has a continuous space in which the battery blocks 21, the battery monitors 30, and the battery controller 40 are disposed in a given layout.

Each of the bottom plate 51, the first walls 52, the second walls 53, and the cover 54 is designed to exhibit electromagnetic shielding properties to block or absorb radio waves. Each of the bottom plate 51, the first walls 52, the second walls 53, and the cover 54 is made from, for example, metallic materials, such as aluminum to exhibit electromagnetic shielding.

The housing 50 which is, as described above, rectangular in shape, is mounted in the vehicle 10 and oriented to have the longer sides thereof extending in the longitudinal direction of the vehicle 10. In FIGS. 3 and 4, the lengthwise direction of the housing 50, i.e., the longitudinal direction of the vehicle 10 is expressed by a Y-direction, while the width direction of the housing 50, i.e., the lateral direction of the vehicle 10 is expressed by a Z-direction. The lower surface of the bottom plate 51 is used as a mounting surface secured to the body of the vehicle 10.

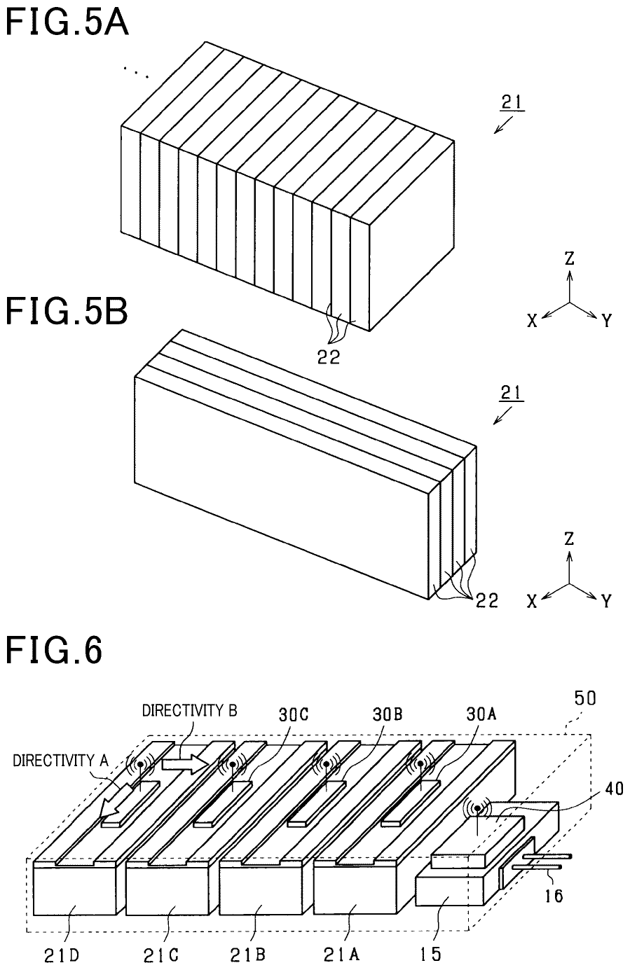

Each of the battery blocks 21 is of a cuboid shape and made of the plurality of electrical cells 22 connected in series with each other. Each of the electrical cells 22 is of a flattened cuboid shape. The electrical cells 22 are, as clearly illustrated in FIG. 5A, stacked on one another in a thickness-wise direction thereof, i.e., the width direction of the housing 50. The electrical cells 22 of each of the battery blocks 21 may be, as illustrated in FIG. 5B, stacked on one another in the longitudinal (i.e., lengthwise) direction of the housing 50. The electrical cells 22 of each of the battery blocks 21 may be electrically connected in parallel to each other.

Each of the battery blocks 21 is, as can be seen in FIGS. 3 and 4, arranged on the bottom plate 51 to have the length extending in the width direction of the housing 50. For the sake of convenience, the four battery blocks 21 are illustrated as being disposed inside the housing 50. There are, therefore, the four battery monitors 30 in the housing 50. In the following discussion, the battery blocks 21 will also be referred to as the first to fourth battery blocks 21A to 21D. Similarly, the battery monitors 30 will also be referred to as the first to fourth battery monitors 30A to 30D. In each of the battery blocks 21, each of the electrical cells 22 has a positive terminal electrically connected to a negative terminal of a respective adjacent one of the electrical cells 22 using a busbar.

The storage chamber 55 has the junction box 15 disposed on the bottom plate 51. The junction box 15 is of a cuboid shape and has the switches SW disposed therein. The junction box 15 is arranged adjacent to the first battery block 21A to have a length extending parallel to the length of the battery blocks 21. The junction box 15 has a height (i.e., thickness) which is lower than those of the battery blocks 21.

The junction box 15 has the battery controller 40 disposed on an upper surface thereof. Each of the battery blocks 21 has a corresponding one of the battery monitors disposed on an upper surface thereof. In the storage chamber 55, the battery controller 40 is located at a level lower than those of the battery monitors 30.

The first battery monitor 30A has the first battery block 21A as a target to be supervised thereby. The second battery monitor 30B has the second battery block 21B as a target to be supervised. The third battery monitor 30C has the third battery block 21C as a target to be supervised thereby. The fourth battery monitor 30D has the fourth battery block 21D as a target to be supervised thereby.

Each of the first to fourth battery monitors 30A to 30D has stored in the second storage device 34 a unique identifying information assigned thereto. When each of the first to fourth battery monitors 30A to 30D is required to transmit the battery information to the battery controller 40, it also outputs the identifying information assigned thereto. This enables the battery controller 40 to determine from which of the first to fourth battery monitors 30A to 30D the battery information has been transmitted.

The secondary antenna 33 of each of the battery monitors 30 is, as can be seen in FIG. 6, designed to be capable of selecting one (which will also be referred to as a first antenna directivity) from a plurality of radio directivities which are different in orientation of central axis from each other. Specifically, the secondary antenna 33 in this embodiment is capable of selecting one from two directivities A and B. Such a structure of the secondary antenna 33 is for providing the directivity best suited for the battery controller 40.

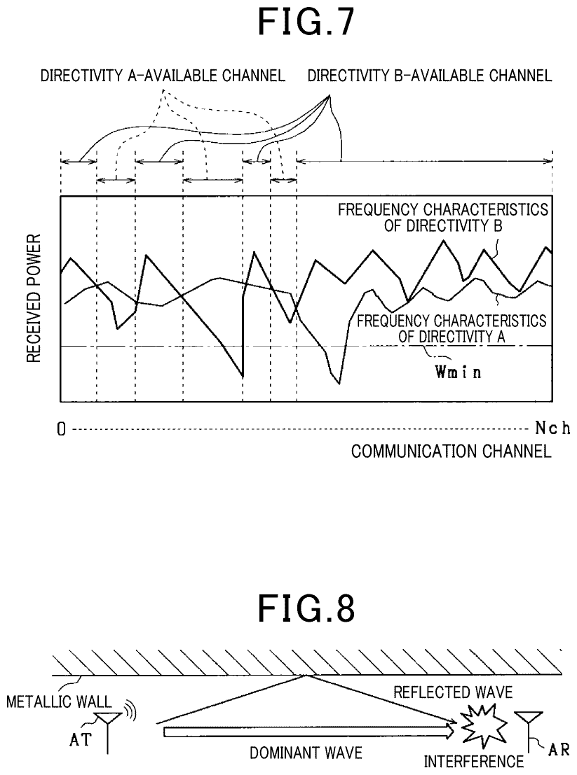

The reason for switching the directivity of the secondary antenna 33 will be described below with reference to FIG. 7. FIG. 7 demonstrates an amount of power of a radio signal which is transmitted from the secondary antenna 33 of the first battery monitor 30A and then received by the primary antenna 43 of the battery controller 40. In FIG. 7, a horizontal axis represents a channel used in radio communication and indicates that the higher the channel is, the higher the frequency of the channel is. A frequency range provided by one channel is defined by a central or median value fc of the frequency of the channel and the bandwidth Δf of the channel, that is, expressed by (fc−Δf/2) to (fc+Δf/2). A high-frequency side of a lower frequency one of a respective adjacent two of the channels may overlap with a low-frequency side of the other.

The lower limit Wmin of the received power shown in FIG. 7 is a threshold value expressing a minimum value of the received power whereby information is properly transmitted from each of the battery monitors 30 to the battery controller 40. When an amount of power received by the primary antenna 43 is lower than the received power lower limit Wmin, it means that it is impossible to properly transmit information between the battery monitors 30 and the battery controller 40.

When the directivity A is selected for the secondary antenna 33, available channels ranging from the lowest channel (0ch) to the highest channel (Nch) includes one in which an amount of power received by the primary antenna 43 is lower than the received power lower limit Wmin. The reason for this will be described below.

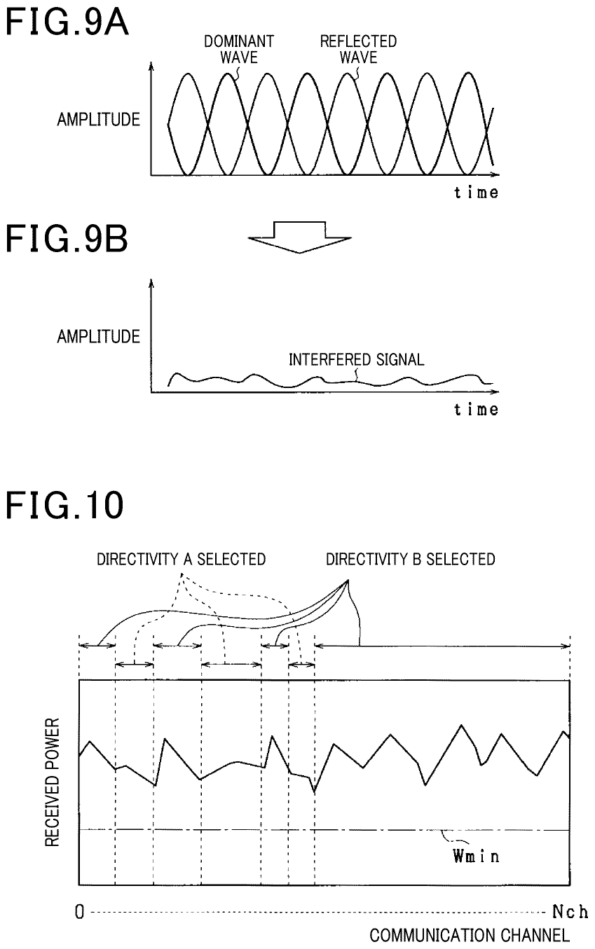

FIG. 8 demonstrates a case where a transmitting antenna AT and a receiving antenna AR are disposed inside a housing made of a metal wall. When a radio signal is transmitted from the transmitting antenna AT, it is diffusely reflected within the housing. This results in interference between a dominant wave component of the radio signal which has been outputted from the transmitting antenna AT, but undergone no reflection and a wave component of the radio signal which has been outputted from the transmitting antenna AT and then reflected on the wall of the housing. A signal resulting from the interference, therefore, as illustrated in FIG. 9B, has an undesirably lowered amplitude, thereby creating a channel in which an amount of power received by the primary antenna 43 is lower than the received power lower limit Wmin. In the example demonstrated in FIGS. 9A and 9B, a phase difference between the reflected wave component and the dominant wave component is near 180 degrees, thus causing the power inputted to the receiving antenna AR to be excessively reduced.

When the directivity of the secondary antenna 33 is, as demonstrated in FIG. 7, changed from the directivity A to the directivity B, it causes an amount of power received by the primary antenna 43 to become higher than or equal to the received power lower limit Wmin in one of the channels where the amount of power received by the primary antenna 43 has been below the received power lower limit Wmin before the directivity of the secondary antenna 33 is changed to the directivity B. The changing to the directivity B also causes one of the channels where the amount of power received by the primary antenna 43 has been below the received power lower limit Wmin theretofore to be changed to another one.

The changing of the directivity of the secondary antenna 33 in the above way when there is a failure in properly transmitting information between one of the battery monitors 30 and the battery controller 40 will cause the amount of power received by the primary antenna 43 to become higher than or equal to the received power lower limit Wmin, thereby achieving proper transmission of information between a corresponding one of the battery monitors 30 and the battery controller 40.

For the reason noted above, in the production process of the battery pack 11, a frequency characteristic (also called a frequency response) of power of a signal which is wirelessly transmitted from each of the battery monitors 30 and then received by the battery controller 40 (e.g., a received signal strength indicator) are measured for each of the directivities A and B. The measured frequency characteristic is used, as shown in FIG. 10, to specify which of the directivities A and B maximizes the power of a signal which is outputted from each of the secondary antennas 33 and then received by the primary antenna 43 for each of the channels.

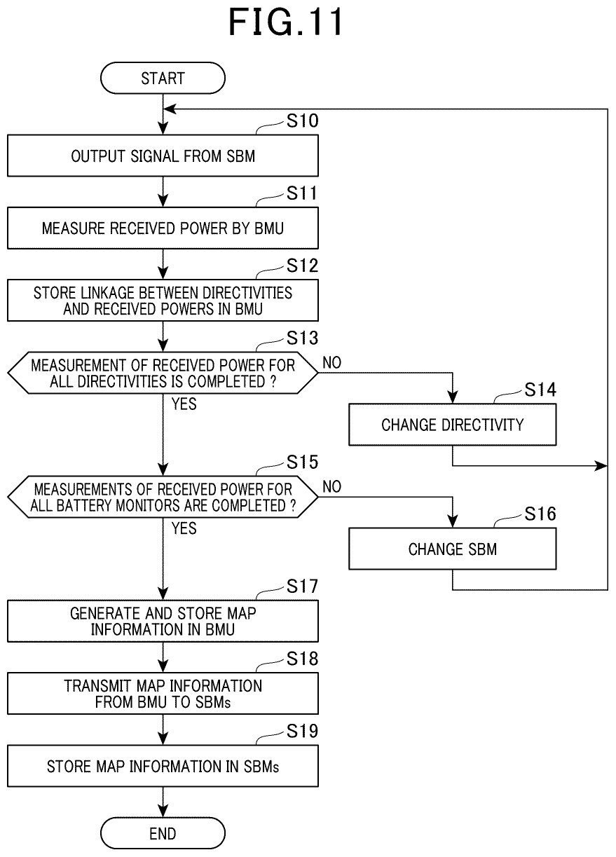

FIG. 11 is a flowchart of an information generating task to produce map information which represents a linkage between a directivity of the secondary antenna 33 which causes an amount of power received by the primary antenna 43 to be maximized and a corresponding one of the channels. This task is performed by the micro controller unit 41 of the battery controller 40 and the monitoring integrated circuit 31 of each of the battery monitors 30 in a production process of the battery pack 11.

First, in step S10, the monitoring integrated circuit 31 of one of battery monitors 30A to 30D transmits from the secondary storage device 34 a radio signal provided when the directivity A is selected. For the sake of simplicity, the following discussion will refer to the first battery monitor 30A. The radio signal includes the identifying information on the first battery monitor 30A.

In step S11, the radio signal is received by the primary antenna 43 of the battery controller 40. The micro controller unit 41 of the battery controller 40 analyzes the received radio signal and calculates a frequency characteristic of power of the radio signal received by the primary antenna 43 which is linked to the channels and provided as received power information about the primary antenna 43. The routine proceeds to step S12 wherein the micro controller unit 41 links among the calculated frequency characteristic, the directivity A, and the identifying information about the first battery monitor 30A which has outputted the radio signal.

The routine proceeds to step S13 wherein the micro controller unit 41 determines whether the measurement of power received by the primary antenna 43 for the directivities A and B of the secondary antenna 33 of the first battery monitor 30A has been completed. If a NO answer is obtained in step S13 meaning that the micro controller unit 41 determines the measurement of received power has not yet been completed, then the routine proceeds to step S14 wherein the directivity of the secondary antenna 33 of the first battery monitor 30A is switched from the directivity A to the directivity B. Subsequently, the routine proceeds to steps S10 to S12 again to link among the calculated frequency characteristic of, the directivity B of, and the identifying information about the first battery monitor 30A.

If a YES answer is obtained in step S13 meaning that the measurement of received power has been completed, then the routine proceeds to step S15 wherein it is determined whether the measurements of received power have been completed for the directivities A and B in all the battery monitors 30A to 30D. If a NO answer is obtained in step S15 meaning that the measurements of received power have not yet been complete, then the routine proceeds to step 16 wherein the battery monitor 30 which has been required to output the radio signal is switched from the first battery monitor 30A to the second battery monitor 30B.

Subsequently, the routine repeats a sequence of steps S10 to S16 in the above way to associate the calculated frequency characteristic of, the directivities of, and pieces of the identifying information on the second to fourth battery monitors 30B to 30D.

If a YES answer is obtained in step S15, then routine proceeds to step S17 wherein the micro controller unit 41 analyzes the linkages, as derived through steps S10 to S16, to make map information (which will also be referred to as directivity information) about a linkage among each of the channels, the directivity of a corresponding one of the channels which maximizes the amount of power received by the primary antenna 43, and the identifying information about a corresponding one of the battery monitors 30. Taking the first battery monitor 30A as an example, the map information includes information representing which of the directivities A and B of the secondary antenna 33 of the first battery monitor 30A maximizes the power of a radio signal received by the primary antenna 43 on one of the channels which is available to achieve radio communication between the battery controller 40 and the first battery monitor 30A.

For instance, the map information includes information representing that the directivity of the secondary antenna 33 which maximizes the power received by the primary antenna 43 on one of the channels where the median value of the frequency is 2.40 GHz is the directivity B, and that the directivity of the secondary antenna 33 which maximizes the power received by the primary antenna 43 on one of the channels where the median value of the frequency is 2.42 Hz is the directivity A.

The micro controller unit 41 stores the map information generated in the above way in the primary storage device 44.

The routine proceeds to step S18 wherein the micro controller unit 41 transmits the map information generated in the above way from the primary antenna 43 to the first to fourth battery monitors 30A to 30D. On one of the channels which is used to transmit the map information, the directivity of each of the secondary antennas 33 is set to one specified by the map information.

The routine proceeds to step S19 wherein the monitoring integrated circuit 31 of each of the battery monitors 30A to 30D stores the map information, as received using the secondary antenna 33, in the secondary storage device 34.

As apparent from the above discussion, the battery monitoring system in this embodiment is capable of specifying the antenna directivity which maximizes a received amount of power of a radio signal, in other words, the quantity of radio communication. Additionally, the battery monitoring system also eliminates the need for frequently generating, for example, the map information after the battery pack 11 leaves the factory.

However, there may be some cases where when the directivity of the secondary antenna 33 is selected as the directivity A or B, the power received by the primary antenna 43 is lower than the received power lower limit Wmin on at least one of the channels. In such an event, the map information may include an instruction to prohibit the channel on which the received power is lower than the received power lower limit Wmin from being used in radio communication.

The map information may alternatively be generated when the battery pack 11 is designed, not in the production process thereof. In this case, the map information may be stored in the primary storage device 44 and the secondary storage device 34 in the production process using a writing device installed on a production line of the battery pack 11. The received power required to such map information may be measured in the following way.

An external measuring device is electrically connected to the battery controller 40 (i.e., the primary antenna 43) and the battery monitors 30 (i.e., the secondary antenna 33). The measuring device works to measure the power of a radio signal which is outputted from each of the battery monitors 30 and received by the primary antenna 43 and calculate the frequency characteristic of the power. Specifically, the measuring device measures a loss of power (e.g., insertion loss) of a radio wave propagated from the secondary antenna 33 to the primary antenna 43. The frequency characteristic (i.e., frequency response) of power received in the primary storage device 44 is calculated by adding a transmission power from the secondary antenna 33 and losses of power in the primary wireless integrated circuit 42, the primary antenna 43, the secondary wireless integrated circuit 32, and the secondary antenna 33 to the loss of power derived by the measuring device.

Before outputting a radio signal to the battery controller 40, each of the battery monitors 30 analyzes the map information to determine which of the directivities A and B should be set to the directivity of the secondary antenna 33 thereof. One of the channels which is used for radio communication between each of the battery monitors 30A to 30D and the battery controller 40 may be determined by a corresponding one of the battery monitors 30A to 30D or alternatively shared as a common channel.

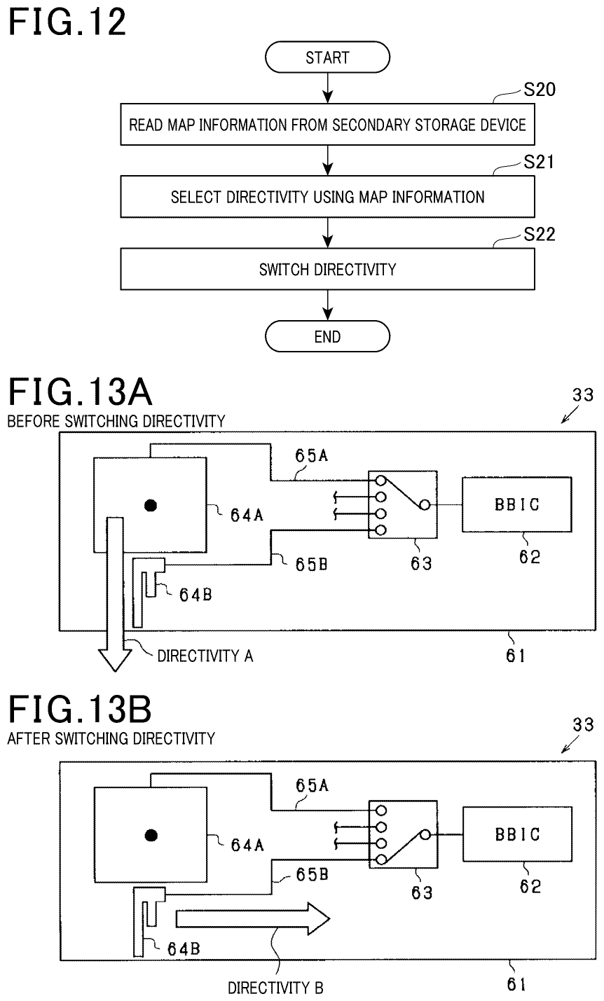

An antenna directivity switching task performed by the monitoring integrated circuit 31 of each of the battery monitors 30 will be described below with reference to FIG. 12.

Upon initiation of the antenna directivity switching task, the routine proceeds to step S20 wherein the monitoring integrated circuit 31 reads the map information from the secondary storage device 34.

The routine proceeds to step S21 wherein the map information, as obtained in step S20, is analyzed to select one of the directivities A and B for use with one of the channels which is employed in radio communication with the battery controller 40.

The routine proceeds to step S22 wherein the directivity of the secondary antenna 33 is changed to one of the directivities A and B which is linked to the channel used in the radio communication in step S21.

Three examples of the structure of the secondary antenna 33 which is capable of changing orientation of the center axis of the directivity thereof will be described below with reference to FIGS. 13A to 15B.

FIGS. 13A and 13B demonstrate the first example of the structure of each of the secondary antennas 33. The secondary antenna 33 in this example is designed to switch among a plurality of types of antenna elements which are different in orientation of the center axis thereof from each other.

The secondary antenna 33 includes the circuit substrate 61, the baseband integrated circuit 62, the changeover switch 63, a plurality of antenna elements, and feeders which are mounted on the circuit substrate 61. The feeders electrically connect the antenna elements and the changeover switch 63 together. FIGS. 13A and 13B illustrate the antenna elements including the first antenna element 64A and the second antenna element 64B and also illustrate the feeders including the first feeder 65A and the second feeder 65B.

The baseband integrated circuit 62 achieves communication with the monitoring integrated circuit 31 using the secondary wireless integrated circuit 32. The baseband integrated circuit 62 connects with the first feeder 65A or the second feeder 65B through the changeover switch 63. When the changeover switch 63, as demonstrated in FIG. 13A, connects the baseband integrated circuit 62 with the first feeder 65A, the first antenna element 64A is selected to be usable. The first antenna element 64A has the directivity A. Alternatively, when the changeover switch 63, as demonstrated in FIG. 13B, connects the baseband integrated circuit 62 with the second feeder 65B, the second antenna element 64B is selected to be usable. The second antenna element 64B has the directivity B.

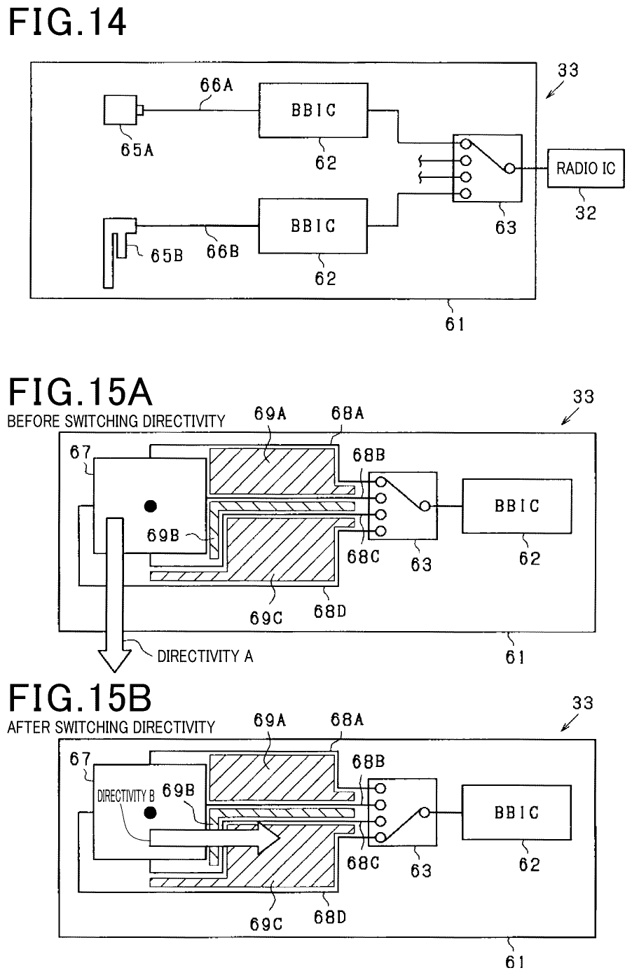

FIG. 14 demonstrates the second example of the secondary antenna 33. The second antenna 33 includes a plurality of baseband integrated circuits 62 one for each feeder and is designed to switch between the baseband integrated circuits 62.

Specifically, the secondary antenna 33 includes the circuit substrate 61, the first and second baseband integrated circuits 62, the changeover switch 63, a plurality of antenna elements, and a plurality of feeders which are mounted on the circuit substrate 61. The feeders electrically connect the antenna elements and the baseband integrated circuits 62 together. FIG. 14 illustrates the antenna elements including the first antenna element 64A and the second antenna element 64B and also illustrates the feeders including the first feeder 66A and the second feeders 66B.

FIGS. 15A and 15B demonstrate the third example of the secondary antenna 33 designed to switch among a plurality of electrical supplies to an antenna element for switching antenna directivities

Specifically, the secondary antenna 33 includes the circuit substrate 61, the baseband integrated circuit 62, the changeover switch 63, the antenna element 67, and the first to fourth feeders 68A to 68D. The antenna element 67 and the first to fourth feeders 68A to 68D are mounted or fabricated on the circuit substrate 61. The antenna element 67 is made of a zeroth-order resonant antenna, e.g., a patch antenna.

The structure in FIGS. 15A and 15B works to four selectable directivities for the secondary antenna 33. For the sake of convenience, the following discussion will refer only to two of the four directivities. When the changeover switch 63, as demonstrated in FIG. 15A, electrically connects the first feeder 68A with the baseband integrated circuit 62, the directivity of the antenna element 67 is set to the directivity A. Alternatively, when the changeover switch 63, as demonstrated in FIG. 15B, electrically connects the fourth feeder 68D with the baseband integrated circuit 62, the directivity of the antenna element 67 is set to the directivity B.

The first to fourth feeders 68A to 68D are disposed to extend substantially parallel to each other on the circuit substrate 61. The circuit substrate 61 has mounted thereon a conductive ground pattern which is, as illustrated by hatch lines, arranged between a respective adjacent two of the feeders 68A to 68D. The ground patterns each serve as a ground connection with the baseband integrated circuit 62. In the third example in FIGS. 15A and 15B, the first ground pattern 69A is disposed between the first feeder 68A and the second feeder 68B. The second ground pattern 69B is disposed between the second feeder 68B and the third feeder 68C. The third ground pattern 69C is disposed between the third feeder 68C and the fourth feeder 68D.

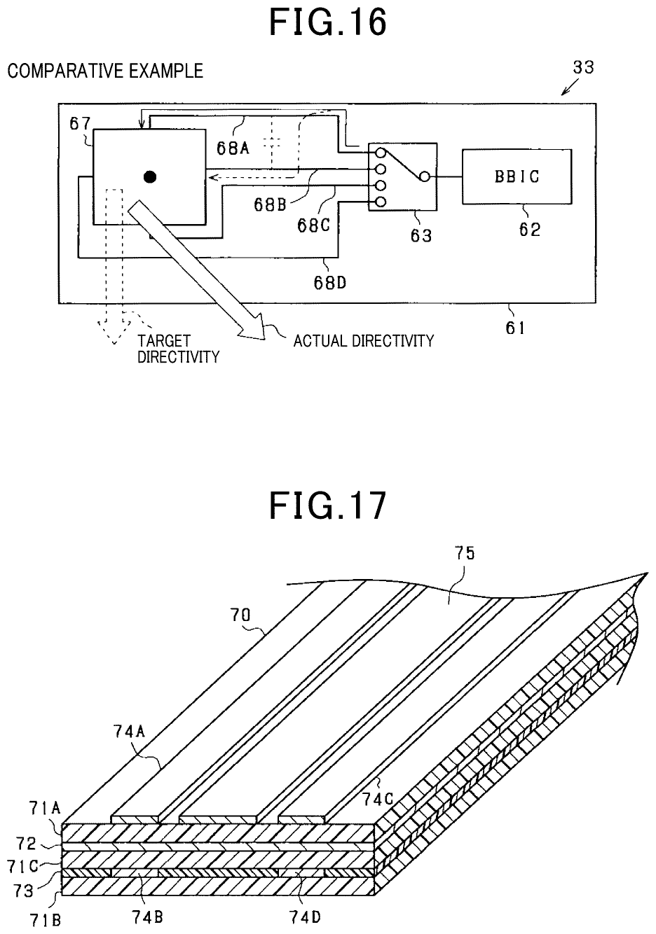

The ground patterns are used to secure the stability in switching the directivity of the secondary antenna 33 to a target one. FIG. 16 illustrates a comparative example of the secondary antenna 33 with no ground patterns. For the sake of convenience, the following discussion will refer to a flow of electrical current through, for example, the first feeder 68A. There is a capacitive coupling created between the first feeder 68A and the second feeder 68B. This causes a portion of current flowing through the first feeder 68A to leak into the second feeder 68B, thereby resulting in a deviation of the directivity of the secondary antenna 33 from the target value.

The structure of the secondary antenna 33 in this embodiment, as illustrated in FIGS. 15A and 15B, has the ground patterns and minimizes a risk that a capacitive coupling may occur between a respective adjacent two of the first to fourth feeders 68A to 68D, thereby ensuring the stability in setting the directivity of the antenna element 67 to the target one.

Generally, feeders connecting with a zeroth-order resonant antenna may be fabricated on different layers of a multi-layered substrate. FIG. 17 illustrates, as an example, the multi-layered substrate 70. The multi-layered substrate 70 includes the first layer 71A, the second layer 71B, and the intermediate layer 71C disposed between the first layer 71A and the second layer 71B. The first layer 71A and the second layer 71B define opposed outer surfaces of the multi-layered substrate 70. The first layer 71A has mounted thereon the first feeder 74A identical in function with the first feeder 68A illustrated in FIGS. 15A and 15B and the third feeder 74C identical in function with the third feeder 68C illustrated in FIGS. 15A and 15B. The second feeder 74B and the fourth feeder 74D which are identical in function with the second feeder 68B and the fourth feeder 68D are disposed between the second layer 71B and the intermediate layer 71C. The insulating layers 73 serving as electrical insulators are disposed adjacent to the second feeder 74B and the fourth feeder 74D between the second layer 71B and the intermediate layer 71C.

The first layer 71A has formed thereon the ground pattern 75 located between the first feeder 74A and the third feeder 74C. The conductive ground pattern 72 is also formed between the first layer 71A and the intermediate layer 71C. This structure also serves to minimize the deviation of the antenna directivity.

Subsequently, beneficial advantages offered by the structure capable of switching the antenna directivity will be described below with reference to two examples.

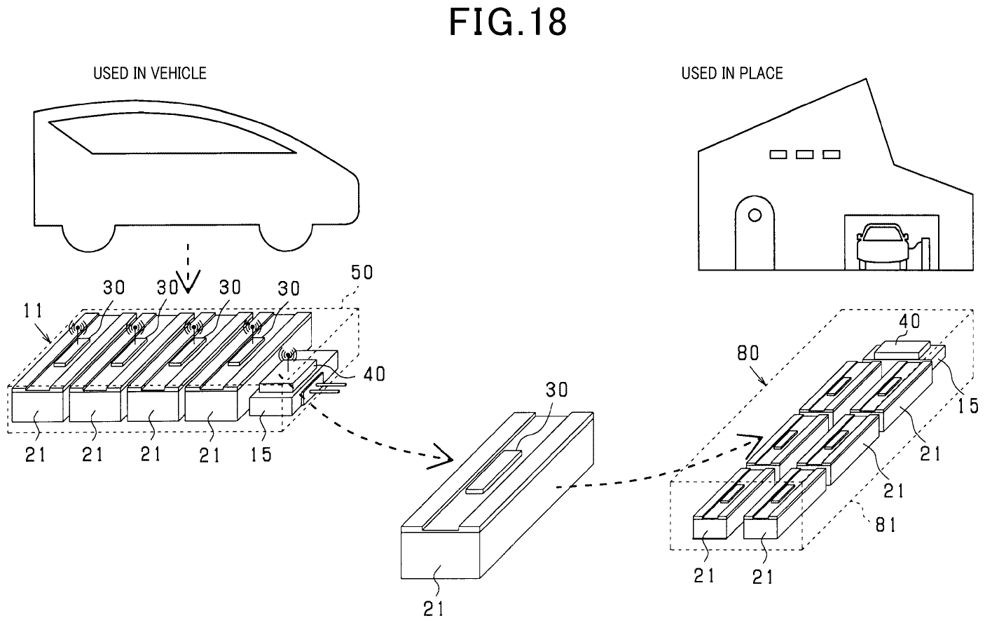

The first example is an example when the battery blocks 21 of the battery pack 11 are reused. The battery pack 11 in this example is installed in the vehicle 10. After being used in the vehicle 10, the battery blocks 21 of the battery pack 11 are reusable for other uses. In an example demonstrated by FIG. 18, the battery blocks 21 are reused from an in-vehicle application to a stationary facility application. The housing 81 of the battery pack 80 is arranged in the stationary facility. The layout of the battery blocks 21, the battery monitors 30, the battery controller 40, and the junction box 15 within the housing 81 is different from that installed in the vehicle 10. The housing 81 used in the stationary facility is different in configuration from that used in the vehicle 10.

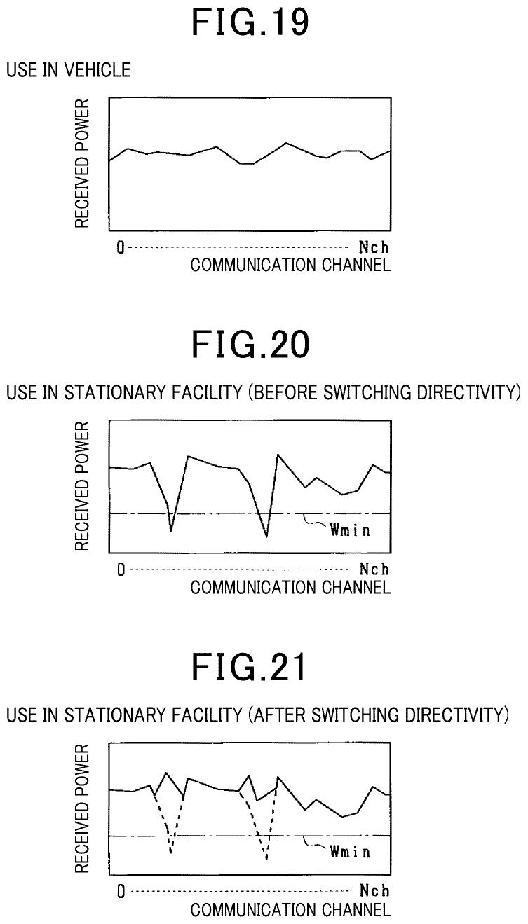

FIG. 19 represents a frequency characteristic of power received by the primary antenna 43 using the map information prepared by the information generating task in FIG. 11 in a case where the battery pack 11 is used in the vehicle 10. In the example in FIG. 19, the antenna directivity which maximizes the received power is linked to each channel.

FIG. 20 represents a frequency characteristic of power received by the primary antenna 43 when the antenna directivity for each channel is specified using the map information generated for the in-vehicle application in a case where the battery pack 80 equipped with the battery blocks 21 is reused for the stationary facility application. In the in-vehicle application, when the received power on each channel becomes higher than or equal to the received power lower limit Wmin, a change in configuration of the housing 81 or layout of component parts within the housing 81 with a change in application of the battery pack will result in a great change in path through which a radio wave is transmitted between the secondary antenna 33 in the housing 81 and the primary antenna 43, which may cause the received power to be lowered below the received power lower limit Wmin. In such a case of reuse of batteries, at least one of a path through which a radio wave is transmitted in a battery housing, the layout of an antenna, and the directivity of the antenna may not be optimized, thereby resulting in deterioration in communication quantity. This requires the need for replacing the antenna with another antenna upon reuse of the battery pack.

When the battery pack is reused for another application, the execution of the information generating task in FIG. 11 enables the antenna directivity which, as demonstrated in FIG. 21, keeps the power received by the primary antenna 43 above the received power lower limit Wmin to be derived on each channel. After the battery pack 80 is produced or completed by mounting the battery blocks 21, the battery monitors 30 installed on the battery blocks 21, and the battery controller 40 in the housing 81 designed for reuse application, the information generating task in FIG. 11 is performed when the battery controller 40 of the battery pack 80 is activated for the first time.

As apparent from the above discussion, the above embodiment ensures stability in radio communication between the battery controller 40 and each of the battery monitors 30 regardless of the configuration of a battery housing used in reuse applications or the layout of component parts installed in the battery housing or without the need for replacing the secondary antennas 33 or the primary antenna 43 with those designed for reuse applications.

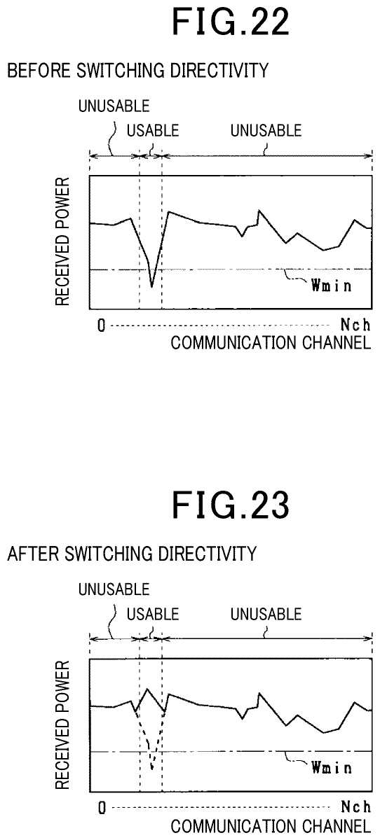

The second example is an example where after leaving the factory, the battery pack 11 is mounted in the vehicle 10. Component parts, such as the battery monitors 30, of the battery pack 11 may fail to operate properly. Noise arising from radio waves outputted from a mobile device used by an occupant in the vehicle 10 may change communication conditions in the vehicle 10. This leads to a risk that one of the channels, as demonstrated in FIG. 22, may become unusable, so that the received power decreases below the received power lower limit Wmin on another available channel. In such an event, keeping the received power above the received power lower limit Wmin on the available channels is, as demonstrated in FIG. 23, achieved by changing the directivity of the secondary antenna 33.

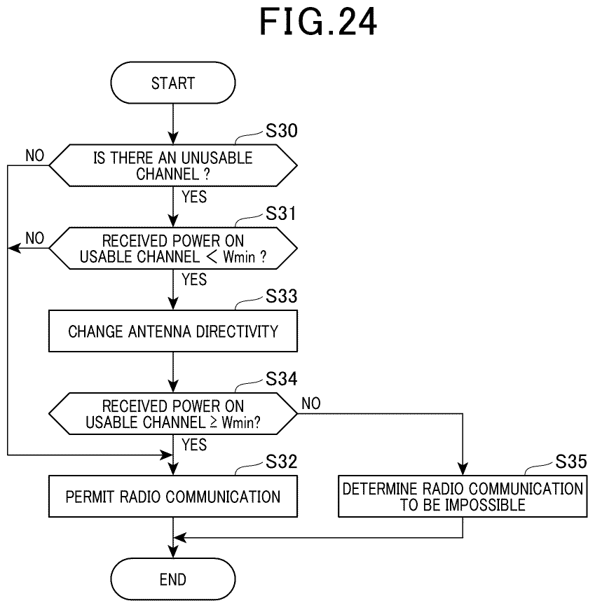

FIG. 24 is a flowchart of a sequence of steps of the antenna directivity switching task performed by the micro controller unit 41 in the second example.

First, the routine proceeds to step S30 wherein it is determined whether there is at least one of the channels which is unusable to achieve radio communication with a selected one of the battery monitors 30.

If a YES answer is obtained in step S30 meaning that there is the unusable channel, then the routine proceeds to step S31 wherein it is determined whether an amount of power received by the primary antenna 43 on the usable channel(s) is lower than the received power lower limit Wmin.

If a NO answer is obtained in step S31 meaning that the received power is higher than or equal to the received power lower limit Wmin or a NO answer is obtained in step S30 meaning that there is no unusable channel, then the routine proceeds to step S32 wherein a radio communication is permitted between the battery controller and a corresponding one of the battery monitors 30.

Alternatively, if a YES answer is obtained in step S31 meaning that the received power is lower than the received power lower limit Wmin, then the routine proceeds to step S33 wherein the directivity of the secondary antenna 33 is switched from the directivity A to the directivity B or from the directivity B to the directivity A.

The routine then proceeds to step S34 wherein a radio signal outputted from a corresponding one of the battery monitors 30 after the directivity of the secondary antenna 33 is changed is received by the primary antenna 43, and then power of the received radio signal is measured and wherein it is determined whether the power received by the primary antenna 43 on the usable channel is higher than or equal to the received power lower limit Wmin.

If a YES answer is obtained in step S34 meaning that the received power is higher than or equal to the received power lower limit Wmin, then the routine proceeds to step S32. Alternatively, if a NO answer is obtained in step S34 meaning that that the received power is lower than the received power lower limit Wmin, then the routine proceeds to step S35 wherein it is determined that it is impossible to achieve the radio communication. A signal indicating that a failure in radio communication is occurring is outputted to a primary control system.

As apparent from the above discussion, this embodiment is capable of enhancing the robustness of the radio communication regardless of deterioration in, for example, radio communication conditions.

### Modification of the First Embodiment

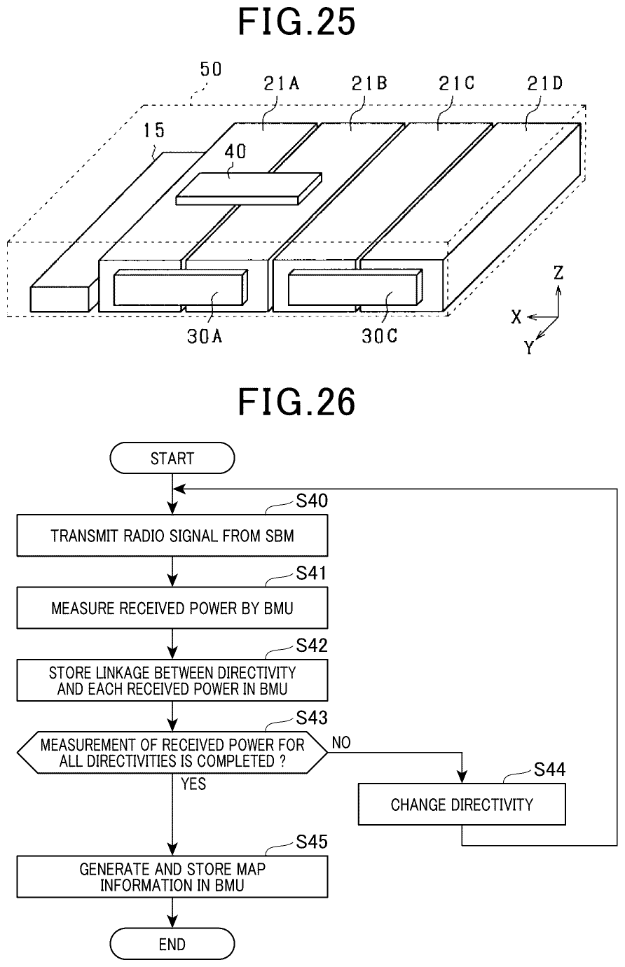

The layout of the battery controller 40 and the battery monitors 30 in the storage chamber 55 of the housing 50 is not limited to that illustrated in FIGS. 3 and 4. For instance, the battery controller 40, as illustrated in FIG. 25, may be secured to upper surfaces of the battery blocks 21. The battery monitors 30 may be attached to side surfaces of the battery blocks 21. For the sake of convenience, the battery blocks 21 are illustrated in FIG. 25 in a simpler manner than in FIG. 3.

At least one of the bottom plate 51, the first walls 52, the second walls 53, and the cover 54 may be made not to have an electromagnetic shielding feature. For instance, the bottom plate 51, the first walls 52, the second walls 53, or the cover 54 may be made from synthetic resin.

Each of the secondary antennas 33 may be designed to have a selected one of three or more directivities oriented to have center axes different from each other. In this case, the directivity of each of the secondary antennas 33 is selectively set to one other than which will cause an amount of power of a radio signal which is transmitted from the secondary antenna 33 and then received by the primary 10) antenna 43 to be the lowest among the channels usable for radio communication between the primary antenna 43 of the secondary antenna 33. The directivity of each of the secondary antennas 33 may alternatively be set to one other than which will maximize or minimize the power received by the primary antenna 43. When there are two or more of the directivities which will cause the received power to be higher than or equal to the received power lower limit Wmin on one of the channels, the map information may be generated which provides the above two or more directivities as being optional on that channel.

### Second Embodiment

The second embodiment will be described below in terms of differences between itself and the first embodiment with reference to the drawings. The second embodiment is capable of switching the directivity of the primary antenna 33 of the battery controller 40 among a plurality of values without changing the directivities of the secondary antennas 33 in order to select the directivity of the primary antenna 43 which is most suitable for the battery monitors 30. The primary antenna 43 in this embodiment is configured to have the same structure as one of those illustrated in FIGS. 13A to 15B and is, thus, capable of switching the directivity of the primary antenna 43 between the directivities A and B.

FIG. 26 is a flowchart of a sequence of steps of a map information generating task to produce map information about a linkage between the directivity of the primary antenna 43 which maximizes an amount of power received by the primary antenna 43 and each channel. This task is performed by the micro controller unit 41 of the battery controller 40 and the monitoring integrated circuit 31 of each of the battery monitors 30 in a production process of the battery pack 11.

After entering the program in FIG. 26, the routine proceeds to step S40 wherein the monitoring integrated circuit 31 of each of the battery monitors 30A to 30D emits a radio signal using the secondary storage device 34. The radio signal includes the identification information about a corresponding one of the battery monitors 30 from which such radio signal is outputted. Cycles in which the battery monitors 30A to 30D output the radio signals are determined not to overlap each other.

The routine proceeds to step S41 wherein the radio signal outputted from each of the battery monitors 30 is received by the primary antenna 43 having the directivity A. The micro controller unit 41 of the battery controller 40 analyzes the received radio signal outputted from each of the battery monitors 30A to 30D and calculates a frequency characteristic of power of the radio signal received by the primary antenna 43 which is linked to a corresponding one of the battery monitors 30A to 30D. The routine proceeds to step S42 wherein the micro controller unit 41 links the calculated frequency characteristic of the received power in relation to each the battery monitors 30A to 30D with the directivity A.

The routine proceeds to step S43 wherein the micro controller unit 41 determines whether the measurement of power received by the primary antenna 43 for each of the directivities A and B has been completed. If a NO answer is obtained in step S43 meaning that the micro controller unit 41 determines the measurement of received power has not yet been completed, then the routine proceeds to step S44 wherein the directivity of the primary antenna 43 is switched from the directivity A to the directivity B. Subsequently, the routine proceeds to steps S40 to S42 again to link the calculated frequency characteristic of the received power in relation to each of the battery monitors 30A to 30D with the directivity B.

If a YES answer is obtained in step S43 meaning that the measurement of power received by the primary antenna 43 for each of the directivities A and B has been completed, then the routine proceeds to step S45 wherein the micro controller unit 41 analyzes the linkage information, as derived in steps S40 to S44, to generate map information (which will also be referred to as directivity information) about a linkage between each channel and the directivity which maximizes the amount of power received by the primary antenna 43 on a corresponding one of the channels. The micro controller unit 41 stores the map information generated in the above way in the primary storage device 44.

The map information may alternatively be generated when the battery pack 11 is designed, not in the production process thereof. In this case, the map information may be stored in the primary storage device 44 in the production process using a writing device installed on a production line of the battery pack 11.

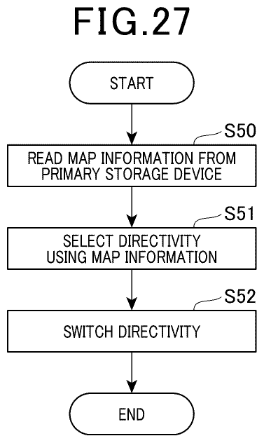

An antenna directivity switching task performed by the micro controller unit 41 of the battery controller 40 will be described below with reference to FIG. 27.

First, in step S50, the map information is red from the primary storage device 44. The routine proceeds to step S51 wherein the map information, as obtained in step S50, is analyzed to select one of the directivities A and B for use with one of the channels which is employed in radio communication with the battery controller 40.

The routine proceeds to step S52 wherein the directivity of the primary antenna 43 is changed to one of the directivities A and B which is linked or associated with the channel used in the radio communication, in other word, selected in step S51.

The above structure is also capable of ensuring the stability in radio communication between the battery controller 40 and each of the battery monitors 30.

### Modification of the Second Embodiment

The map information about the linkage between each of the channels and the antenna directivity which maximizes the power received by the secondary antenna 33 on a corresponding one of the channels may alternatively be generated as a function of an amount of power received by the secondary antenna 33 instead of that received by the primary antenna 43. Such map information is generated in association with each of the battery monitors 30 (i.e., each of the secondary antennas 33). How to generate the map information will be described below. The battery controller 40 first outputs a radio signal from the primary antenna 43 whose directivity is set to the directivity A to each of the secondary antennas 33. The monitoring integrated circuit 31 of each of the battery monitors 30A to 30D analyzes the radio signal received by the secondary antenna 33 to calculate a frequency characteristic of power of the received radio signal and then links or associates the calculated frequency characteristic with the directivity A. The monitoring integrated circuit 31 of each of the battery monitors 30A to 30D outputs information about the linkage of the frequency characteristic thereof with the directivity A from the secondary antenna 33 to the primary antenna 43. The micro controller unit 41 receives the linkage information, as outputted from each of the battery monitors 30A to 30D, using the primary antenna 43. Subsequently, the battery controller 40 outputs a radio signal from the primary antenna 43 whose directivity is set to the directivity B to each of the secondary antennas 33. In the same manner as the directivity A, the micro controller unit 41 receives the linkage information about the frequency characteristic and the directivity B, as outputted from each of the battery monitors 30A to 30D, using the primary antenna 43. The micro controller unit 41 analyzes the linkage information to generate map information about a linkage between each of the channels and the directivity which maximizes the power received by a corresponding one of the secondary antennas 33 on a corresponding one of the channels. The calculation of the frequency characteristic and/or the linkage between the frequency characteristic and the antenna directivity may alternatively be made by the battery controller 40 (i.e., the micro controller unit 41) instead of the battery monitors 30 (i.e., the monitoring integrated circuits 31).

The primary antenna 43 may be designed to have a selected one of three or more directivities oriented to have center axes different from each other. In this case, the directivity of the primary antenna 43 is selectively set to one other than which will cause an amount of power of a radio signal which is received by the primary antenna 43 or each of the secondary antennas 33 to be the lowest among the channels usable for radio communication between the primary antenna 43 of each of the secondary antennas 33. The directivity of the primary antenna 43 may alternatively be set to one other than which will maximize or minimize the power received by the primary antenna 43 or each of the secondary antennas 33. When there are two or more of the directivities which will cause the received power to be higher than or equal to the received power lower limit Wmin on one of the channels, map information may be generated which provides the above two or more directivities as being optional on that channel.

In addition to the primary antenna 43, each of the secondary antennas 33 may be, like in the first embodiment, designed to have one selected from a plurality of directivities.

### Third Embodiment

The third embodiment will be described below in terms of differences between itself and the first embodiment with reference to the drawings. This embodiment is designed to specify the optimum directivity of each of the secondary antennas 33 in a production process of the battery pack 80, as demonstrated in FIG. 18, for reuse applications and obtain information about a history of an electrical state of each of the battery blocks 21.

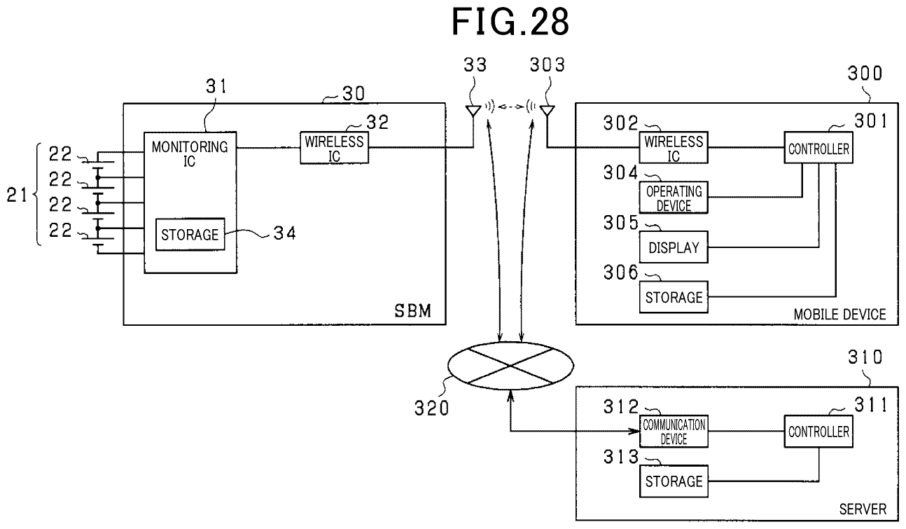

FIG. 28 illustrates a battery monitoring system, the mobile device 300 serving as an inspection device used with the battery monitoring system, and the external server 310. In FIG. 28, the same reference numbers as employed in FIG. 2 refer to the same parts, and explanation thereof in detail will be omitted here.

The mobile device 300 is a portable device which is designed to determine whether the battery blocks 21 are usable for reuse applications and manipulated by an operator. The mobile device 300 includes the controller 301, the wireless integrated circuit 302, the antenna 303, the operating device 304, the display 305, and the storage device 306.

The controller 301 is substantially made of a microcomputer which performs a variety of tasks. The wireless integrated circuit 302 is connected to the controller 301 through a wired connection and includes a wireless MCU (i.e., a Micro Control Unit) and an RF device (i.e., a high-frequency device module). The wireless integrated circuit 302 receives data from the controller 301 and outputs it from the antenna 303 in a wireless mode. The wireless integrated circuit 302 also receives data through the antenna 303 and then delivers it to the controller 301. The storage device 306 is made of a non-volatile memory other than a ROM, e.g., a non-transitory tangible storage medium.

The operating device 304 is manipulated by the operator and connected to the controller 301 through a wired connection. The operating device 304 is made of, for example, a touch panel, a touch display, a hardware key, e.g., a keyboard, or a pointing device, such as a mouse.

The display 305 connects with the controller 301 through a wired connection and works to visually present results of the task performed by the controller 301. The display 305 is made of, for example, a touch panel or a touch display. The display 305 represents records of operating states of the battery blocks 21 which are wirelessly transmitted from the battery monitors 30 installed on the battery blocks 21.

The external server 310 includes the controller 311, the communication device 312, and the storage device 313. The controller 311 is substantially made of a microcomputer and works to perform a variety of tasks. The communication device 312 is connected to the controller 311 through a wired connection. The communication device 312 is communicable with the mobile device 300 and the battery monitors 30 using the communication network 320. The communication network 320 is implemented by at least one of a wired network and a wireless network. The storage device 313 is made of a non-volatile memory other than a ROM, e.g., a non-transitory tangible storage medium.

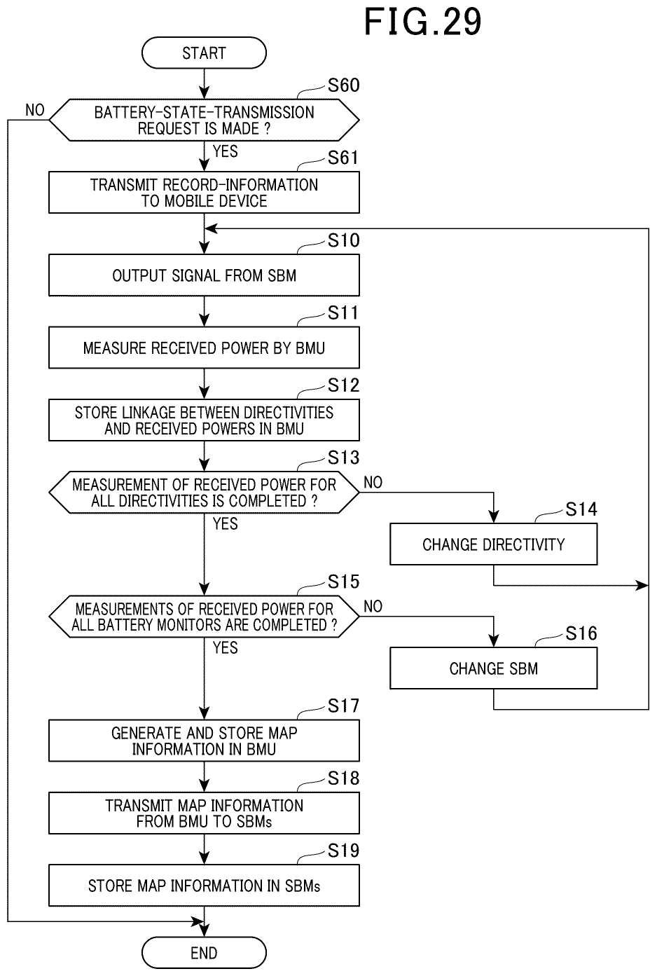

FIG. 29 is a flowchart of a sequence of steps of a map information generating task to produce map information which represents a linkage between a directivity of each of the secondary antennas 33 which causes an amount of power received by the primary antenna 43 to be maximized and a corresponding one of the channels. This task is performed by the mobile device 300, the micro controller unit 41, and the monitoring integrated circuit 31 of each of the battery monitors 30 in a production process of the battery pack 80 used for reuse applications. The task in FIG. 29 is initiated when a condition where the battery controller 40 and the mobile device 300 are placed in wired or wireless connection mode is met. In FIG. 29, the same step numbers as those in FIG. 11 refer to the same operations, and explanation thereof in detail will be omitted here.

After entering the program in FIG. 29, the routine proceeds to step S60 wherein the micro controller unit 41 (i.e., the battery controller 40) determines whether a request for transmitting information about records of state of the battery blocks 21 has been made by the mobile device 300. Such a record-information transmission request is produced by the operator. Specifically, the operator connects the mobile device 300 and the micro controller unit 41 together to be communicable with each other in the wired or wireless connection mode and manipulates the operating device 304 to transmit the record-information transmission request from the mobile device 300 to the battery controller 40. If a YES answer is obtained in step S60 meaning the micro controller unit 41 determines that the record-information transmission request is made, then the routine proceeds to step S61 wherein information about a record of a state of each of the battery blocks 21 (which will also be referred to as battery-state-record information) stored in the primary storage device 44 is outputted to the mobile device 300. The battery-state-record information includes at least one of first to sixth pieces 1) to 6) of information discussed below. The first to fifth pieces of information represent a time-dependent change in state of each of the battery blocks 21. The sixth piece of information represents a parameter which is not contingent on a record of usage of the battery blocks 21.

1) A temperature record of a change in temperature of each of the battery blocks 21 with time.
2) A voltage record of a change in voltage at each of the battery blocks 21 with time.
3) A current record of a change in current flowing in each of the battery blocks 21 with time.
4) Data used to assess a health property(ies) of each of the battery blocks 21, such as at least one of an SOC (State-Of-Charge), an SOH (State-Of-Health), a remaining electrical energy or power, a variation in self-discharge rate, and an internal resistance.
5) Data used to determine an expected service life of each of the battery blocks 21, such as a date of manufacture, a date of beginning of use, an energy-handling capacity, or an energy-generating ability or actual capacity.
6) Data about an economic operator which supplies the battery blocks 21, such as a battery manufacturer, a model code, a manufacturing place, a manufacturing date, a rated capacity, a minimum voltage, a nominal voltage, a maximum voltage, and a service temperature range of the battery blocks 21.

The mobile device 300 visually represents the battery-state-record information on the display 305. The operator analyzes the information on the display 305 and detects the conditions of the battery blocks 21.

After step S61, the operations in steps S10 to S19 are performed. This generates the map information which specifies the directivity most suitable for each of the secondary antennas 33 of the battery pack 80 used for reuse applications.

The above structure is capable of specifying the directivity most suitable for each of the secondary antennas 33 in a production process of the battery pack 80 used for reuse applications and detecting the electrical states of the battery blocks 21 reused.

### Modification of the Third Embodiment

All or at least one of the above-described first to sixth pieces of the battery-state-record information may be stored in the storage device 313 of the external server 310. For instance, the battery-state-record information may be periodically transmitted from each of the battery monitors through the communication network 320 to the external server 310 to cyclically update the battery-state-record information already retained in the storage device 313 of the external server 310. The mobile device 300 may also receive all or at least one of the above-described first to sixth pieces of the battery-state-record information from 10) the external server 310 through the communication device 312, the communication network 320, and the wireless integrated circuit 302.

When it is required to reuse the battery blocks 21, the above information is transmitted from the external server 310 to the mobile device 300 to enable the mobile device 300 to detect the conditions of the battery blocks 21 needed for reuse applications. This enables the high-reliability battery-state-record information to be obtained in a case where the external server 310 is protected from tampering using, for example, blockchain techniques.

It is advisable that the battery-state-record information retained in the storage device 313 of the external server 310 include data which is usually low in the number of updating times, e.g., the above-described sixth piece of the battery-state-record information.

### Fourth Embodiment

The fourth embodiment will be described below in terms of differences between itself and the first embodiment with reference to the drawings. The directivity selecting task may be performed after the vehicle 10 is transferred to a user, not in the production process of the battery pack 11. This embodiment is designed to permit the directivity selecting task to be performed when the vehicle 10 is parked or the assembled battery 20 is being electrically charged by the external battery charger CM.

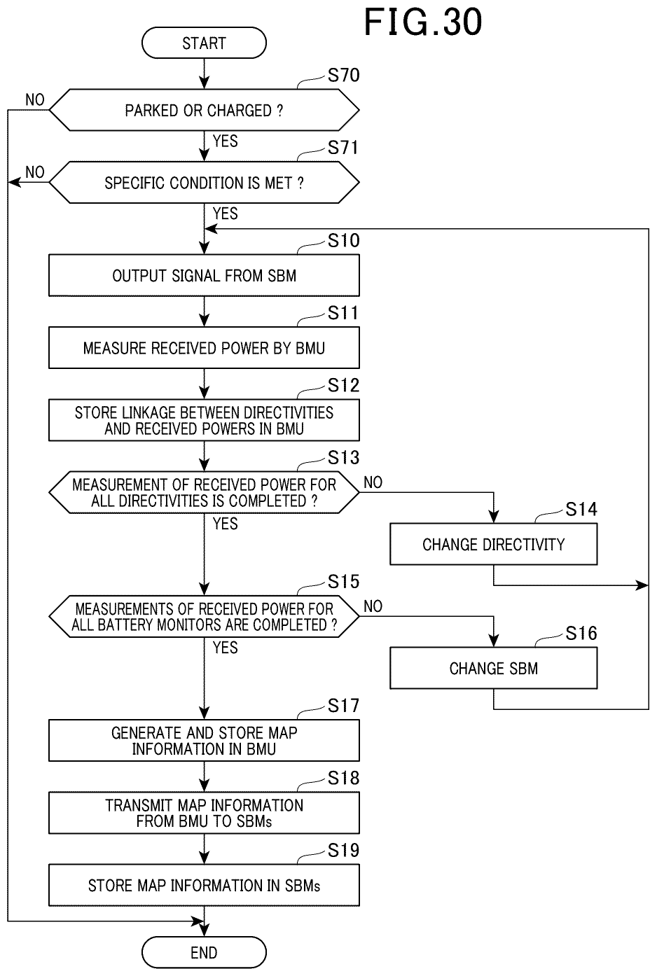

FIG. 30 is a flowchart of a sequence of steps of a map information generating task to produce map information which represents a linkage between a directivity of each of the secondary antennas 33 which causes an amount of power received by the primary antenna 43 to be maximized and a corresponding one of the channels. This task is performed by the micro controller unit 41 of the battery controller 40 and the monitoring integrated circuit 31 of each of the battery monitors 30. In FIG. 30, the same step numbers as those in FIG. 11 refer to the same operations, and explanation thereof in detail will be omitted here.

After entering the program in FIG. 30, the routine proceeds to step S70 wherein the micro controller unit 41 determines whether the first condition or the second condition is met. The first condition is a condition where the vehicle 10 is parked. The second condition is an condition where the assembled battery mounted in the parked vehicle 10 is being electrically charged by the external battery charger CM. The determination in step S70 is made for enhancing the accuracy in measuring an amount of power received by the primary antenna 43.

A radio signal received by the primary antenna 43 usually has a frequency characteristic (i.e., a frequency response) which varies due to mechanical vibration of the moving vehicle 10. This leads to a risk that the accuracy of the map information representing a linkage between the antenna directivity which maximizes an amount of power received by the primary antenna 43 and each of the channels may deteriorate or a period of time required to generate the map information may be increased. It is, therefore, preferable that the measurement of the received power is made when no vibration is occurring. This is the reason for providing the first condition. For instance, when a start switch or an ignition switch which is actuated by the user of the vehicle 10 to permit the vehicle 10 to move or start the vehicle 10 is determined to be turned off, the first condition may be determined to be met.

When the assembled battery 20 is being charged by the external battery charger CM, it means that the vehicle is parked, so that no mechanical vibration is occurring in the vehicle 10. This is the reason for providing the second condition.

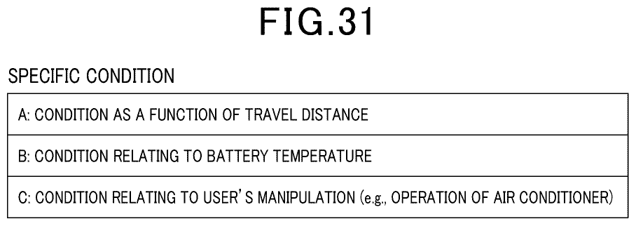

If a NO answer is obtained in step S70 meaning that none of the first and second conditions are met, then the micro controller unit 41 does not perform the map information generating task. Alternatively, if a YES answer is obtained meaning that at least one of the first and second conditions is met, then the routine proceeds to step S71 wherein the micro controller unit 41 determines whether a specific condition is met. The specific condition is a condition used to determine whether a radio wave propagation path between the primary antenna 43 and each of the secondary antennas 33 with the housing 50 has been greatly changed from that when the power received by the primary antenna 33 was measured according to the program in FIG. 11 in the production process of the battery pack 11. The specific condition may include at least one of the first to third conditions A to C demonstrated in FIG. 31.

A Condition where the distance traveled by the vehicle (e.g., a cumulative distance shown on an odometer) exceeds a reference distance Lth. An increase in travel distance of the vehicle 10 may cause bolts used to secure the cover 54 to a base of the housing 50 to be undesirably loosen, which results in a change in inside volume of the storage chamber 55. This may lead to a risk that the radio wave propagation paths in the housing 50 may be greatly changed from the initial ones, thereby resulting in a great change in frequency response of power received by the primary antenna 43. The map information generating task is performed cyclically. It is, therefore, preferable that the reference distance Lth is incremented each time when the travel distance exceeds the reference distance Lth. Instead of the travel distance, a travel time (e.g., a cumulative time) for which the vehicle has been moved.
B Condition where the temperature of each of the battery blocks 21 exceeds a reference temperature. A rise in temperature of the battery blocks 21 usually result in thermal expansion of the housing 50, thereby changing the geometry of the radio wave propagation paths. The reference temperature is selected to be higher than the temperature of the battery blocks 21 when the power received by the primary antenna 33 was measured in the production process of the battery pack 11.
C Condition where an air conditioner installed in the vehicle 10 is manipulated by the user of the vehicle 10. For instance, the fact that the air conditioner has been operated by the user usually means that an ambient temperature around the battery pack 11 has been changed from that when the battery pack 11 was manufactured, thereby resulting in a great change in geometry of the radio wave propagation paths.

If a YES answer is obtained in step S71 meaning that the specific condition is met, then the routine proceeds to step S10 wherein the micro controller unit 41 transmits instruction signals from the primary antenna 43 to the secondary antennas 33 to output radio signals. When the monitoring integrated circuit 31 of each of the battery monitors 30 determines that the instruction signal has been received, it transmits the radio signal from a corresponding one of the secondary antennas 33.

In step S11, the temperature of, the degree of humidity in, and/or the air pressure in the storage chamber 55 may be measured by sensors when it is required to measure the received power and then linked with antenna directivities in the map information.

The above-described embodiment, as described above, works to determine the directivity of each of the secondary antennas 33 as a function of a change in geometry of the radio wave propagation paths within the housing 50, thereby improving the quality of radio communication between each of the battery monitors 30 and the battery controller 40.

### Fifth Embodiment

The fifth embodiment will be described below in terms of differences between itself and the fourth embodiment with reference to the drawings. The fifth embodiment is designed to permit the directivity selecting task to be performed when the vehicle 10 is moving.

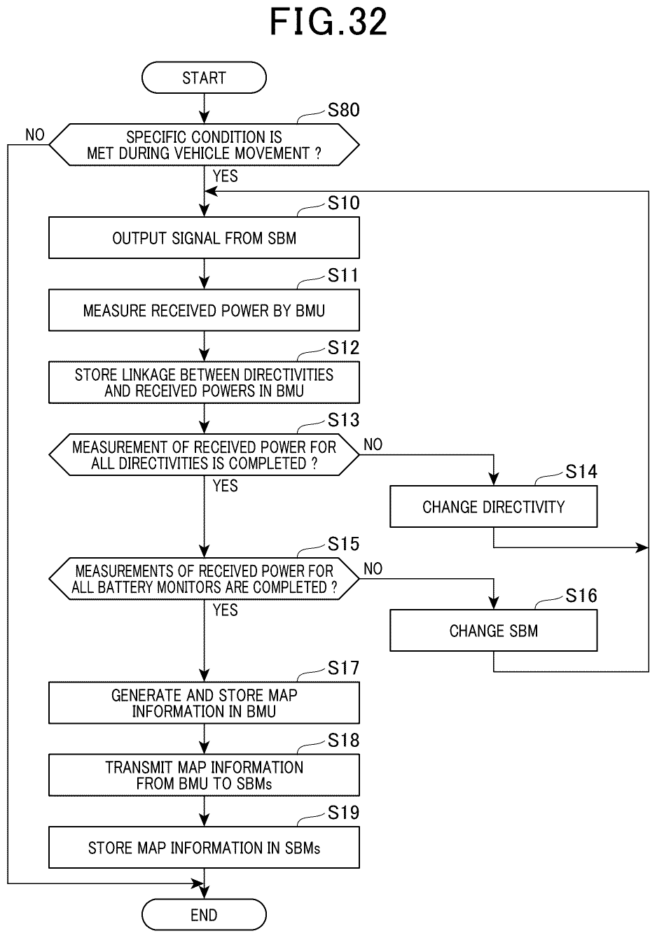

FIG. 32 is a flowchart of a sequence of steps of the map information generating task to produce map information representing a linkage of the antenna directivity which maximizes an amount of power received by the primary antenna 43 with each channel. This task is performed by the micro controller unit 41 of the battery controller 40 and the monitoring integrated circuit 31 of each of the battery monitors 30. In FIG. 32, the same step numbers as employed in FIG. 11 refer to the same operations, and explanation thereof in detail will be omitted here.

After entering the program in FIG. 32, the routine proceeds to step S80 wherein the micro controller unit 41 determines whether a specific condition is met when the vehicle 10 is moving. The operation in step S80 is for enhancing the accuracy in measuring an amount of power received by the primary antenna 43. The specific condition is a condition used to determine whether a radio wave propagation path between the primary antenna 43 and each of the secondary antennas 33 with the housing 50 has been greatly changed during movement of the vehicle 10 to detect, for example, the fact that mechanical vibration generating during movement of the vehicle 10 has increased or electrical noise has increased in the storage chamber 55. For instance, the specific condition may include a condition where an electrical current flowing in the assembled battery 20 has become higher than a reference current value and/or mechanical vibration derived by an acceleration sensor to measure a degree of acceleration of the vehicle 10 has exceeded a reference value.

If a YES answer is obtained in step S80 meaning that the micro controller unit 41 determined that the specific condition is met, then the routine proceeds to step S10 (see FIG. 11).

The above-described embodiment works to ensure a required degree of quality of communication between each of the battery monitors 30 and the battery controller 40 regardless of a change in geometry of the radio wave propagation paths within the housing 50 during the movement of the vehicle 10.

### Sixth Embodiment

The sixth embodiment will be described below in terms of differences between itself and the fourth and fifth embodiments with reference to the drawings. The sixth embodiment is designed to update the map information when a malfunction is occurring in the battery pack 11.

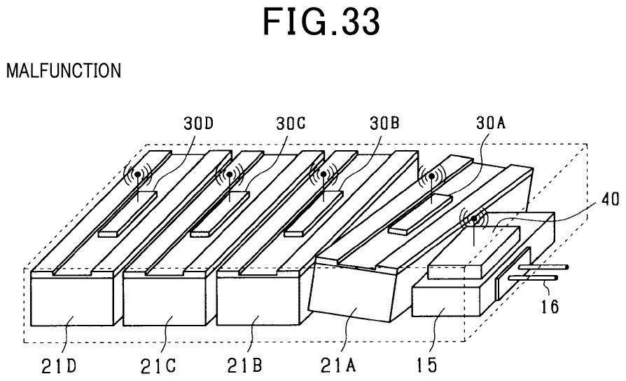

FIG. 33 demonstrates an example where the battery pack 11 is malfunctioning. In FIG. 33, the same reference numbers as employed in FIGS. 3 and 4 refer to the same parts, and explanation thereof in detail will be omitted here. In the example illustrated in FIG. 33, the position of the first battery block 21A is shifted from an initial position. Such a shift usually results in a great change in geometry of the radio wave propagation paths between the battery controller 40 and each of the battery monitors 30A to 30D, which leads to a great deviation of a frequency response of power received by the primary antenna 43 from that measured in the production process of the battery pack 11.

Accordingly, when the radio wave propagation paths are determined to have been greatly changed, the map information is re-generated or updated.

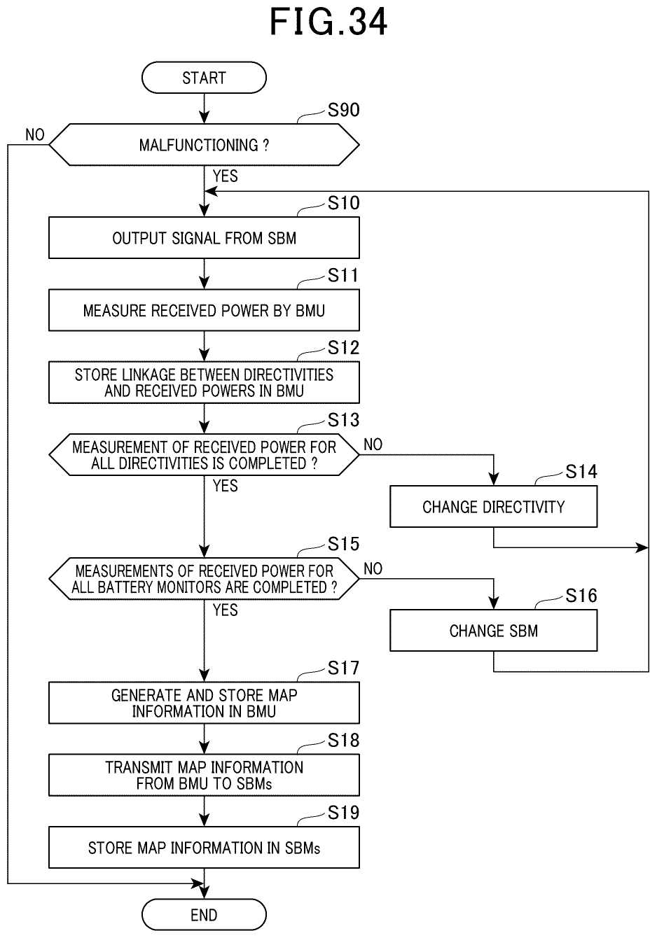

FIG. 34 is a flowchart of a sequence of steps of the map information generating task to produce map information representing a linkage of the antenna directivity which maximizes an amount of power received by the primary antenna 43 with each channel. This task is performed by the micro controller unit 41 of the battery controller 40 and the monitoring integrated circuit 31 of each of the battery monitors 30. In FIG. 34, the same step numbers as employed in FIG. 11 refer to the same operations, and explanation thereof in detail will be omitted here.

After entering the program in FIG. 34, the routine proceeds to step S90 wherein the micro controller unit 41 determines whether the battery pack 11 is malfunctioning, e.g., the battery pack 11 is geometrically deformed. The malfunction of the battery pack 11 is caused by, for example, one of factors wherein the layout of the battery blocks 21 (or the battery monitors 30 and/or the battery controller 40 within the storage chamber 55), each of the battery monitors 30, and/or the battery controller 40 is changed or shifted from a proper one within the storage chamber 55, the cover 54 is misaligned from the base of the housing 50, a voltage anomaly of the electrical cells 22 of the battery blocks 21, water enters the battery blocks 21, smoke is detected in the storage chamber 55, and an airbag system installed in the vehicle 10 is actuated.

If a YES answer is obtained in step S90 meaning that the micro controller unit 41 detects the malfunction of the battery pack 11, then the routine proceeds to step S10 (see FIG. 11).

This embodiment is, therefore, capable of ensuring a required degree of quality of radio communication between each of the battery monitors 30 and the battery controller regardless of the occurrence of the malfunction of the battery pack 11.

### Seventh Embodiment

The seventh embodiment will be described below in terms of differences between itself and the first embodiment with reference to the drawings. This embodiment works to generate the map information using a communication error rate in a radio communication between the primary antenna 43 and each of the secondary antenna 33 instead of the power received by the primary antenna 43.

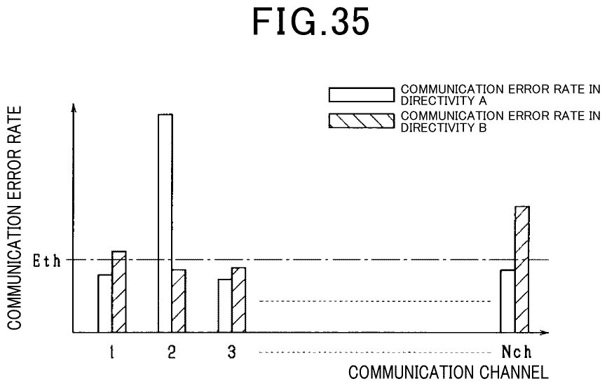

In a production process of the battery pack 11, this embodiment, as demonstrated in FIG. 35, measures a communication error rate during communication of a radio signal from each of the battery monitors 30 on each channel for each of the directivities A and B of each of the secondary antennas 33. The measured communication error rates are used to determine which of the directivities A and B of each of the secondary antennas 33 causes a corresponding one of the communication error rates to drop below a predetermined threshold Eth. The directivity A or B of each of the secondary antennas 33 which causes the communication error rate to exceed the threshold Eth is not used.

In the example in FIG. 35, the first channel is linked with the directivity A. The second channel is linked with the directivity B. The third channel is linked with the directivities A and B.

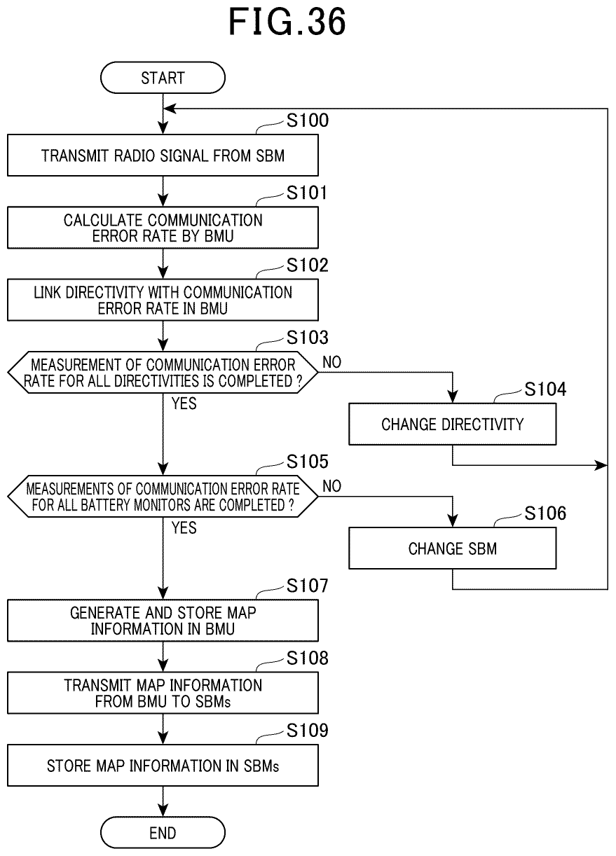

FIG. 36 is a flowchart of a sequence of steps of the map information generating task to produce map information representing a linkage of the antenna directivity with each channel. This task is performed by the micro controller unit 41 of the battery controller 40 and the monitoring integrated circuit 31 of each of the battery monitors 30 in the production process of the battery pack 11.

After entering the program in FIG. 36, the routine proceeds to step S100 wherein the monitoring integrated circuit 31 of a selected one of the battery monitors 30A to 30D selects the directivity A of the secondary antenna 33 and outputs a radio signal from the secondary storage device 34. For the sake of convenience, the following discussion will refer to the first battery monitor 30A selected. The radio signal includes the identification information about the first battery monitor 30A.

The routine then proceeds to step S101 wherein the radio signal outputted from the first battery monitor 30A is received by the primary antenna 43, and the micro controller unit 41 analyzes the received radio signal to calculate the communication error rate. The routine proceeds to step S102 wherein the micro controller unit 41 links among the measured communication error rate, the directivity A, and the identification information about the first battery monitor 30A.

The routine proceeds to step S103 wherein the micro controller unit 41 determines whether the measurement of the communication error rate has been completed for each of the directivities A and B in the first battery monitor 30A. If a NO answer is obtained meaning that the micro controller unit 41 determines that the measurement of the communication error rate is not yet completed, then the routine proceeds to step S104 wherein the directivity of the secondary antenna 33 of the first battery monitor 30A is switched from the directivity A to the directivity B. Subsequently, the operations in steps S100 and S102 are performed again to link among or associate the communication error rate, the directivity B, and the identification information about the first battery monitor 30A.

Alternatively, if a YES answer is obtained in step S103 meaning that the micro controller unit 41 determines that the measurement of the communication error rates is completed for the directivities A and B, then the routine proceeds to step S105 wherein it is determined whether the measurement of the communication error rates has been completed for the directivities A and B in all the battery monitors 30A to 30D. If a NO answer is obtained meaning that the micro controller unit 41 determines that the measurement of the communication error rates is not yet completed for all the battery monitors 30A to 30D, then the routine proceeds to step S106 wherein the second battery monitor 30B is selected instead of the first battery monitor 30A. Subsequently, the operations in steps S100 and S106 are performed again to link among the communication error rate, a corresponding one of the directivities A and B, and the identification information about a corresponding one of the first to fourth battery monitors 30A to 30D.

If a YES answer is obtained in step S105, the routine proceeds to step S107 wherein the micro controller unit 41 analyzes the linkage information derived by the operations in steps S100 to S106 and generates the map information (i.e., directivity information) representing a linkage among each channel, the directivity of each of the secondary antennas 33 which causes the communication error rate to be lower than or equal to the threshold Eth on a corresponding one of the channels, and the identifying information of a corresponding one of the battery monitors 30. The micro controller unit 41 then stores the map information in the primary storage device 44. One of the directivities of each of the secondary antennas 33 which causes a corresponding one of the communication error rates to be the lowest on a corresponding one of the channels may be linked in the map information.

The routine proceeds to step S108 wherein the micro controller unit 41 transmits the map information generated in the above way from the primary antenna 43 to the first to fourth battery monitors 30A to 30D. On one of the channels which is used to transmit the map information, the directivity of each of the secondary antennas 33 is set to one specified by the map information. The routine proceeds to step S109 wherein the monitoring integrated circuit 31 of each of the battery monitors 30A to 30D stores the map information, as received using the secondary antenna 33, in the secondary storage device 34.

The above-described seventh embodiment offers substantially the same beneficial advantages as those in the first embodiment and may be modified to include the structure in at least one of the second to sixth embodiments.

### Eighth Embodiment

The eighth embodiment will be described below in terms of differences between itself and the first embodiment with reference to the drawings. This embodiment is designed to use a difference between an amount of power received by the primary antenna 43 and the noise floor created in the radio communication instead of the received power.

This embodiment is designed to transmit a radio signal from each of the battery monitors 30 for each of the directivities A and B in the production process of the battery pack 11, calculate a difference between an amount of power received by the primary antenna 43 and the noise floor (which will also be referred to as a power-noise difference), and determine one of the directivities A and B which causes the power-noise difference to be higher than or equal to a given threshold Wth on each channel. Usually, the higher the power-noise difference, the higher a degree of margin of communication against the noise. One or some of the antenna directivities which causes the power-noise difference to be lower than the threshold Wth is not used in this embodiment.

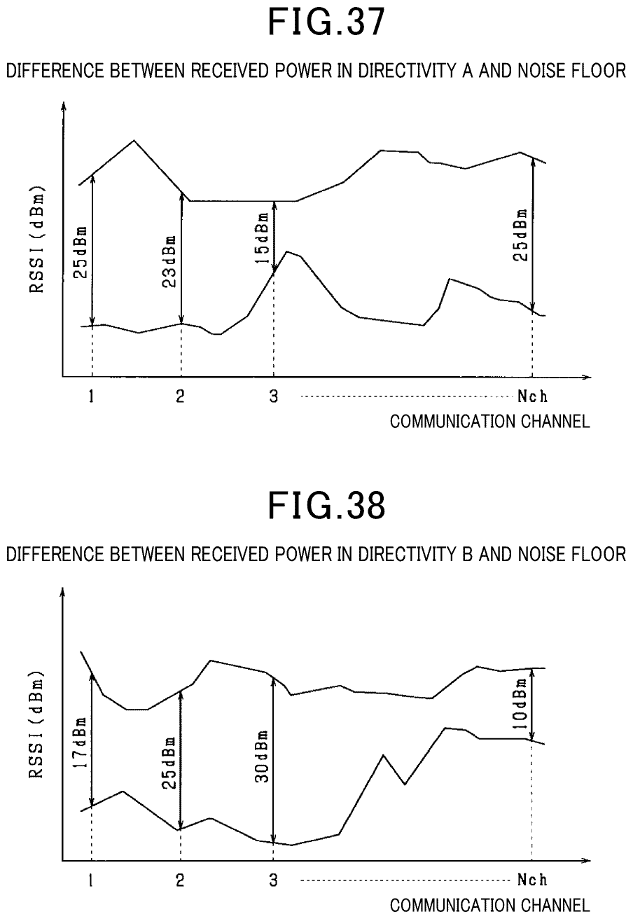

FIG. 37 represents a frequency characteristic (i.e., a frequency response) of a difference between an amount of power received by the primary antenna 43 and the noise floor (which will also be referred to below as a power-noise difference) when the directivity of the secondary antenna 33 is set to the directivity A. FIG. 38 represents a frequency characteristic of the power-noise difference when the directivity of the secondary antenna 33 is set to the directivity B.

In the examples shown in FIGS. 37 and 38, the power-noise difference ΔW when the directivity A is selected on the first channel is 25 dBm, while the power-noise difference ΔW when the directivity B is selected on the first channel is 17 dBm. When the threshold Wth is determined to be 20 dBm, the directivity A is, therefore, linked to the first channel.

The power-noise difference ΔW when the directivity A is selected on the second channel is 23 dBm, while the power-noise difference ΔW when the directivity B is selected on the second channel is 25 dBm. The directivities A and B are, therefore, linked to the second channel.

The power-noise difference ΔW when the directivity A is selected on the third channel is 15 dBm, while the power-noise difference ΔW when the directivity B is selected on the third channel is 30 dBm. The directivity B is, therefore, linked to the third channel.

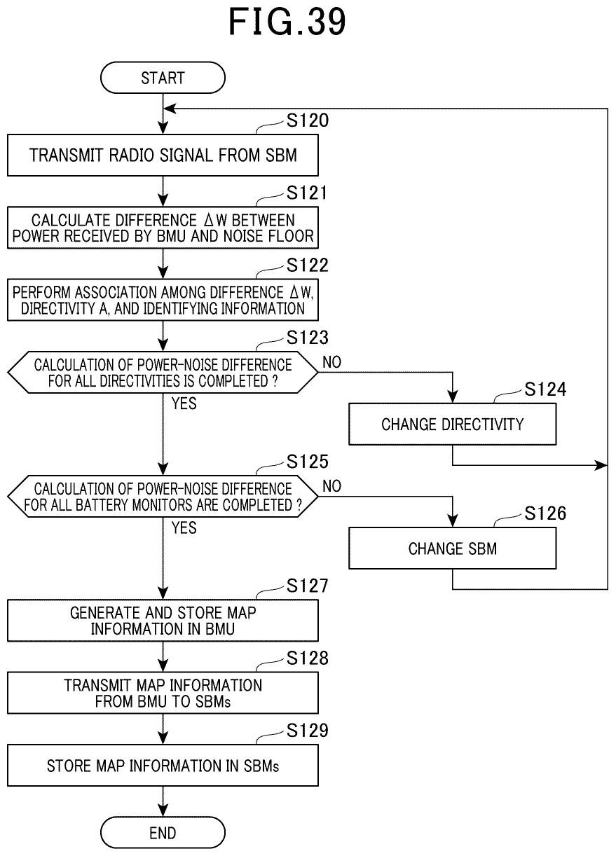

FIG. 39 is a flowchart of a sequence of steps of the map information generating task to produce map information representing a linkage of the antenna directivity with each channel. This task is performed by the micro controller unit 41 of the battery controller 40 and the monitoring integrated circuit 31 of each of the battery monitors 30 in the production process of the battery pack 11.

After entering the program in FIG. 39, the routine proceeds to step S120 wherein the monitoring integrated circuit 31 of a selected one of the battery monitors 30A to 30D selects the directivity A of the secondary antenna 33 and outputs a radio signal from the secondary storage device 34. For the sake of convenience, the following discussion will refer to the first battery monitor 30A selected. The radio signal includes the identification information about the first battery monitor 30A.

The routine then proceeds to step S121 wherein the radio signal outputted from the first battery monitor 30A is received by the primary antenna 43, and the micro controller unit 41 analyzes the received radio signal to calculate the power-noise difference ΔW. The noise floor used to calculate the power-noise difference ΔW may be stored in advance in the primary storage device 44. The routine proceeds to step S122 wherein the micro controller unit 41 links among the power-noise difference ΔW, the directivity A, and the identification information about the first battery monitor 30A.

The routine proceeds to step S123 wherein the micro controller unit 41 determines whether the calculation of the power-noise difference ΔW has been completed for each of the directivities A and B in the first battery monitor 30A. If a NO answer is obtained meaning that the micro controller unit 41 determines that the calculation of the power-noise difference ΔW is not yet completed, then the routine proceeds to step S124 wherein the directivity of the secondary antenna 33 of the first battery monitor 30A is switched from the directivity A to the directivity B. Subsequently, the operations in steps S120 and S122 are performed again to link among the power-noise difference ΔW, the directivity B, and the identification information about the first battery monitor 30A.

Alternatively, if a YES answer is obtained in step S123 meaning that the micro controller unit 41 determines that the calculation of the power-noise difference ΔW has been completed, then the routine proceeds to step S125 wherein it is determined whether the calculation of the power-noise difference ΔW has been completed for the directivities A and B in all the battery monitors 30A to 30D. If a NO answer is obtained in step S125 meaning that the micro controller unit 41 determines that the calculation of the power-noise difference ΔW is not yet completed for all the battery monitors 30A to 30D, then the routine proceeds to step S126 wherein the second battery monitor 30B is selected instead of the first battery monitor 30A. Subsequently, the operations in steps S120 and S126 are performed again to link among the power-noise difference ΔW, a corresponding one of the directivities A and B, and the identification information about a corresponding one of the first to fourth battery monitors 30A to 30D.

If a YES answer is obtained in step S125, the routine proceeds to step S127 wherein the micro controller unit 41 analyzes the linkage information derived by the operations in steps S120 to S126 and generates the map information (i.e., directivity information) representing a linkage among each channel, the directivity of each of the secondary antennas 33 which causes the power-noise difference ΔW to be higher than or equal to the threshold Wth on a corresponding one of the channels, and the identifying information of a corresponding one of the battery monitors 30. The micro controller unit 41 then stores the map information in the primary storage device 44. One of the directivities of each of the secondary antennas 33 which causes a corresponding one of the power-noise differences ΔW to be maximized on a corresponding one of the channels may be linked in the map information.

The routine proceeds to step S128 wherein the micro controller unit 41 transmits the map information generated in the above way from the primary antenna 43 to the first to fourth battery monitors 30A to 30D. On one of the channels which is used to transmit the map information, the directivity of each of the secondary antennas 33 is set to one specified by the map information. The routine proceeds to step S129 wherein the monitoring integrated circuit 31 of each of the battery monitors 30A to 30D stores the map information, as received using a corresponding one of the secondary antennas 33, in the secondary storage device 34.

The above-described eighth embodiment ensures a required degree of quality of radio communication between the battery controller 40 and each of the battery monitors regardless of a difference in the power-noise difference ΔW among the channels. The eighth embodiment may be modified to include the structure in at least one of the second to seventh embodiments.

### Ninth Embodiment

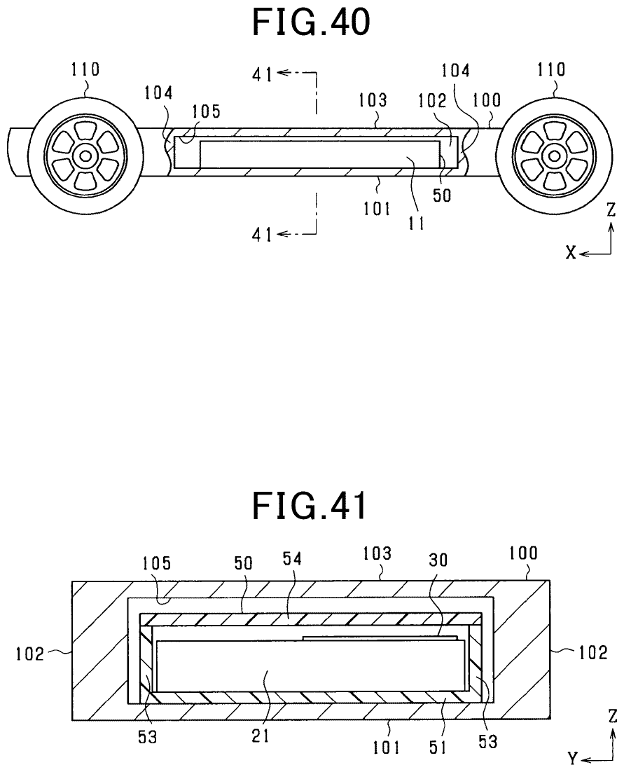

The ninth embodiment will be described below in terms of differences between itself and the above-described embodiments with reference to FIGS. 40 and 41. In FIGS. 40 and 41, the same reference numbers as employed in the above embodiments refer to the same parts, and explanation thereof in detail will be omitted here. FIG. 41 is a cross-sectional view taken along the line 41-41 in FIG. 40.

A vehicle shown in FIG. 40 includes the chassis 100 and the wheels 110. The chassis 100 is made from metal and defines a body of the vehicle. The chassis 100 includes the chassis bottom plate 101 extending in the longitudinal direction of vehicle, the side plates 102, the chassis top plate 103, and the end plates 104. The side plates 102 extend upward from sides of the chassis bottom plate 101 which are opposed to each other in a width direction of the vehicle. The chassis top plate 103 extends to cover the side plates 102 from above. The end plates 104 extend to cover ends of the chassis bottom plate 101, ends of the side plates 102, and ends of the chassis top plate 103. The chassis bottom plate 101, the side plates 102, the chassis top plate 103, and the end plates 104 have inner surfaces defining the storage chamber 105 in which the battery pack 11 is installed.

The bottom plate 51 of the housing 50 is disposed on the chassis bottom plate 101. The chassis top plate 103 and the cover 54 of the housing 50 are located away from each other through an air gap. The bottom plate 51, the first walls 52, the second walls 53, and the cover 54 are made from synthetic resin which has no electromagnetic shielding properties. A radio signal emitted from the primary antenna 43 or each of the secondary antennas 33, therefore, passes through the housing 50. The metallic chassis 100, however, reflects a radio wave thereon.

At least one of the bottom plate 51, the first walls 52, the second walls 53, and the cover 54 may be made from synthetic resin. For instance, the cover 54 may be made from resin.

The storage chamber 105 diffusely reflects a radio wave therein. The storage chamber 105 may also have a change in radio communication condition therein due to reuse of the battery pack 11. It is, therefore, preferable to use the features of one or some of the above-described embodiments with the structure illustrated in FIGS. 40 and 41.

### Tenth Embodiment

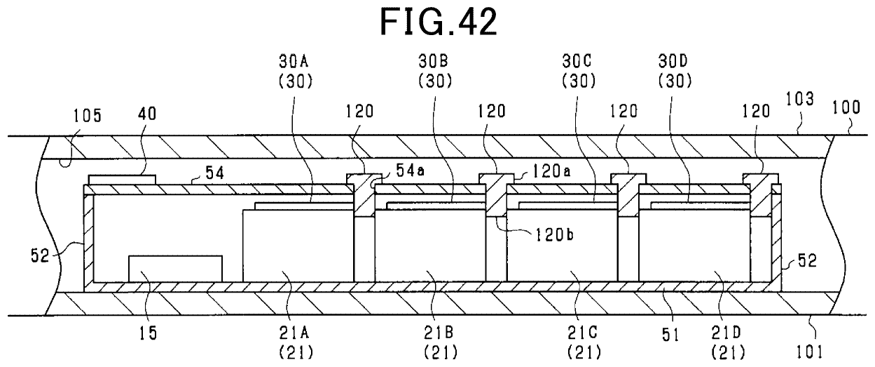

The tenth embodiment will be described below in terms of differences between itself and the ninth embodiment with reference to FIG. 42. In FIG. 42, the same reference numbers as employed in the above-described embodiments refer to the same parts, and explanation thereof in detail will be omitted here.

The battery controller 40 is arranged outside the housing 50 within the storage chamber 105. Specifically, the battery controller 40 is secured to an upper surface of the cover 54.

The cover 54, the first walls 52, the second walls 53, and the bottom plate 51 are each made from metallic material. This structure, therefore, requires the need to have a feature for achieving electrical communication between inside and outside the housing 50, i.e., between each of the battery monitors 30A to 30D disposed in the housing 50 and the battery controller 40 disposed outside the housing 50.

The battery pack 11 is equipped with the relaying devices 120 working as communication connectors. Each of the relaying devices 120 includes the antenna 120a disposed on an upper surface of the cover 54 and the shaft 120b which extends downward from the antenna 120a and have an outer diameter smaller than that of the antenna 120a. The cover 54 has formed therein the through-holes 54a through which the shafts 120b pass. The through-hole 54a are arranged in the cover 54 in alignment with each other in the lengthwise direction of the cover 54. The antennas 120a are located on the upper surface of the cover 54. Each of the shafts 120b extends through one of the through-holes 54a. The relaying devices 120 are mounted one for each of the antennas 120a. In other words, the relaying devices 120 are provided one for each of the battery monitors 30. The antennas 120a may be covered with a radio-wave transmissible member.

Each of the through-holes 54a is closed by the antenna 120a of a corresponding one of the relaying devices 120. A sealing member may be disposed between each of the antennas 120a and the upper surface of the cover 54.

The secondary wireless integrated circuit 32 of each of the battery monitors 30 is electrically connected to a corresponding one of the antennas 120a using a communication wire disposed in or on the shaft 120b. This enables each of the battery monitors 30 to wirelessly communicate with the battery controller 40 through a corresponding one of the antennas 120a and the primary antenna 43.

The above structure also causes a radio wave to be diffusely reflected within the storage chamber 105. The storage chamber 105 may also undergo a change in radio communication condition therein due to reuse of the battery pack 11. It is, therefore, preferable to use the features of one or some of the above-described embodiments with the structure illustrated in FIG. 42.

### Eleventh Embodiment

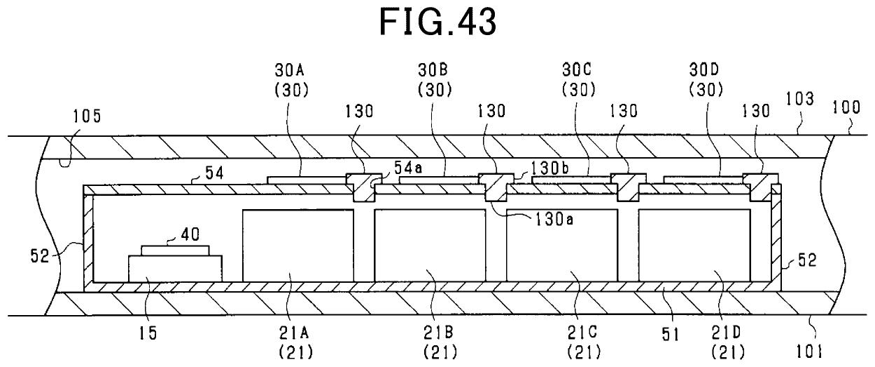

The eleventh embodiment will be described below in terms of differences between itself and the ninth embodiment with reference to FIG. 43 in which the same reference numbers as employed in the above-described embodiments refer to the same parts, and explanation thereof in detail will be omitted here.

The battery controller 40 is secured to an upper surface of the junction box 15 within the housing 50. The first to fourth battery monitors 30A to 30D are located outside the housing 50 within the storage chamber 105. Specifically, the first to fourth battery monitors 30A to 30D are firmly mounted on the upper surface of the cover 54. This structure, therefore, requires the need to have a feature for achieving electrical communication between inside and outside the housing 50, i.e., between the battery controller 40 located inside the housing 50 and each of the battery monitors 30A to 30D disposed outside the housing 50.

The battery pack 11 is equipped with the relaying devices 130 working as communication connectors. Each of the relaying devices 130 includes the connector 130b disposed on the upper surface of the cover 54 and the antenna 130a extending downward from the connector 130b. The cover 54 has formed therein the through-holes 54a through which the antennas 130a pass. The through-hole 54a are arranged in the cover 54 in alignment with each other in the lengthwise direction of the cover 54. The relaying devices 130 are provided one for each of the battery monitors 30. The antennas 130a may be covered with a radio-wave transmissible member.

Each of the through-holes 54a is closed by the connector 130b of the antenna 130a of a corresponding one of the relaying devices 130. A sealing member may be disposed between each of the antennas 130a and the upper surface of the cover 54.

The secondary wireless integrated circuit 32 of each of the battery monitors 30 is electrically connected to a corresponding one of the antennas 130a using a communication wire disposed in the connector 130b. This enables each of the battery monitors 30 to wirelessly communicate with the battery controller 40 through a corresponding one of the antennas 130a and the primary antenna 43.

The above structure also causes a radio wave to be diffusely reflected within the storage chamber 105. The storage chamber 105 may also have a change in radio communication condition therein due to reuse of the battery pack 11. It is, therefore, preferable to use the feature of each of the above-described embodiments with the structure illustrated in FIG. 43.

### Twelfth Embodiment

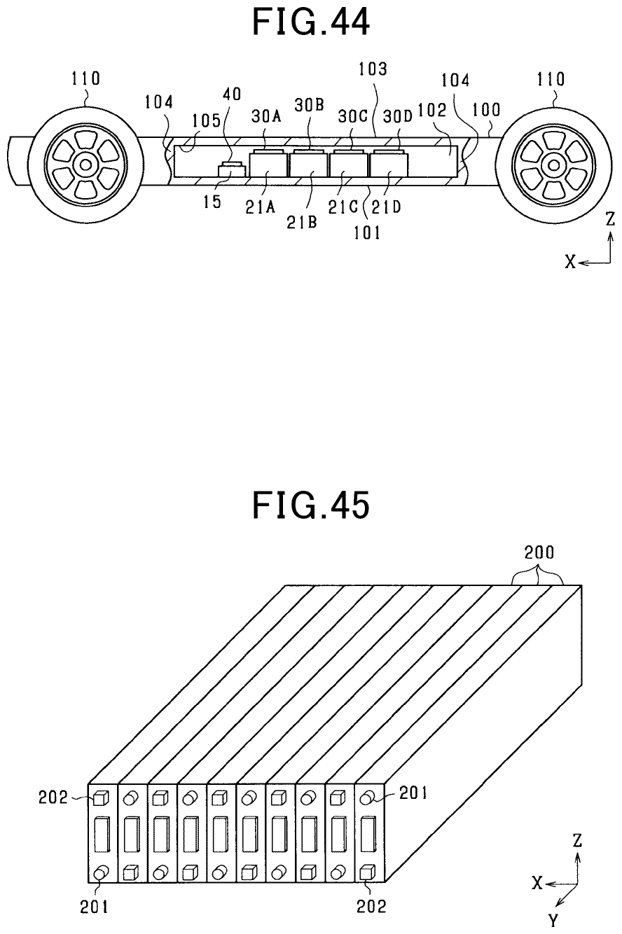

The twelfth embodiment will be described below in terms of differences between itself and the above-described embodiments with reference to FIG. 44 in which the same reference numbers as employed in the above-described embodiments refer to the same parts, and explanation thereof in detail will be omitted here.

The battery pack 11 in this embodiment, as can be seen in FIG. 44, does not include the housing 50. The battery blocks 21A to 21D, the battery monitors 30A to 30D, and the battery controller 40 are disposed directly inside the storage chamber 105 of the chassis 100. Such a structure is usually referred to as an MTP (Module to Platform).

The above structure also causes a radio wave to be diffusely reflected within the storage chamber 105. The storage chamber 105 may also have a change in radio communication condition therein due to reuse of the battery pack 11. It is, therefore, preferable to use one or some of the features of the above-described embodiments with the structure illustrated in FIG. 44.

### Other Embodiments

Each of the above embodiments may be modified in the following ways.

In the above-described embodiments, each of the battery blocks 21 of the battery pack 11 includes the plurality of electrical cells 22. The battery blocks 21 are electrically connected together in series with each other. The battery pack 11 may alternatively be designed to have a so-called CTP (Cell to Pack) structure in which all the electrical cells 22 are electrically connected in series with each other and arranged directly within the storage chamber 105 of the chassis 100. An example of the CTP structure is illustrated in FIG. 45. The electrical cells 200 each of which is oriented to have a length extending in the width direction of the vehicle are disposed in the storage chamber 105. A first one of a respective adjacent two of the electrical cells 200 has the positive terminal 201 electrically connected to the negative terminal 202 of a second one of the adjacent electrical cells 200 using a busbar, not shown. The battery monitors 30 are preferably provided one for each of the electrical cells 200.

Instead of the CTP structure, the battery pack 11 may alternatively be designed to have a CTC (Cell to Chassis) structure in which the chassis 100 has formed therein a storage chamber in which the electrical cells 200 are arranged.

The storage chamber of each of the CTP and CTC structures is, like the above-described embodiments, configured to have at least a portion which diffusely reflects a radio wave thereon and also has a change in radio communication condition therein due to reuse of the battery pack 11. It is, therefore, preferable to use one or some of the features of the above-described embodiments with the CTP or CTC structure.

Each of the above-described embodiments following the third embodiment may be modified to include the structure of the second embodiment which is configured to selectively change the directivity of the primary antenna 43.

A mobile or moving object in which the battery monitoring system is mounted is not limited to an automotive vehicle, but the battery monitoring system may be mounted in aircraft or ships. The control system (e.g., the battery controller 40) may be mounted on a stationary place.

The controllers or how to construct them referred to in this disclosure may be realized by a special purpose computer which is equipped with a processor and a memory and programmed to execute one or a plurality of tasks created by computer-executed programs or alternatively established by a special purpose computer equipped with a processor made of one or a plurality of hardware logical circuits. The controllers or operations thereof referred to in this disclosure may alternatively be realized by a combination of an assembly of a processor with a memory which is programmed to perform one or a plurality of tasks and a processor made of one or a plurality of hardware logical circuits. Computer-executed programs may be stored as computer executed instructions in a non-transitory computer readable medium.

The above embodiments realize the following unique structures.

### First Structure

A battery monitoring system comprises:
battery monitors (30, 30A to 30D) which are provided one for each of a plurality of batteries (21, 21A to 21D, 200) and work to monitor states of the batteries;
a battery controller (40); and
a storage chamber (55, 105) which has at least a portion configured to reflect a radio wave thereon and in which the batteries, the battery monitors, and the battery controller are arranged, wherein
the battery controller includes a primary antenna (43) used in radio communications with the battery monitors,
each of the battery monitors includes a secondary antenna (33) used in radio communication with the battery controller,
each of the secondary antennas and/or the primary antenna is configured to selectively have a first antenna directivity that is one of a plurality of directivities whose center axes are different in orientation from each other, and
the first antenna directivity excludes one of the directivities which causes a degree of quality of radio communication between the primary antenna and a corresponding one of the secondary antennas to be minimized or the lowest among the directivities on a channel used for the radio communication.

### Second Structure

The battery monitoring system as set forth in the first structure, wherein on the channel used for the radio communication between the primary antenna and each of the secondary antennas, one of the directivities which causes an amount of power received by the battery controller or a corresponding one of the battery monitors to be higher than or equal to a given threshold (Wmin) is selected as the first antenna directivity.

### Third Structure

The battery monitoring system as set forth in the second structure, wherein on the channel used for the radio communication between the primary antenna and each of the secondary antennas, one of the directivities which causes the received amount of power to be maximized and higher than or equal to the given threshold selected as the first antenna directivity.

### Fourth Structure

The battery monitoring system as set forth in the second structure, wherein each of the battery monitors includes a secondary storage device (34) stores therein directivity information representing a linkage between each of channels usable for radio communication between a corresponding one of the secondary antennas and the primary antenna and one of the directivities which causes the received amount of power to be higher than or equal to the given threshold on a corresponding one of the channels, and wherein
each of the battery monitors uses the directivity information retained in the secondary storage device to determine one of the directivities which is linked with one of the channels which is used in the radio communication as the first antenna directivity of a corresponding one of the secondary antennas.

### Fifth Structure

The battery monitoring system as set forth in the fourth structure, wherein when a specific condition is determined to be met, the battery controller outputs an instruction signal from the primary antenna to each of the battery monitors to instruct a corresponding one of the battery monitors to transmit a radio signal from a corresponding one of the secondary antennas for each of the directivities,
when receiving the instruction signal, each of the battery monitors works to transmit the radio signal from a corresponding one of the secondary antennas to the battery controller,
the battery controller receives the radio signal, as transmitted from each of the battery monitors for each of the directivities, using the primary antenna and measures an amount of power of the radio signal received by the primary antenna on each of the channels,
the battery controller uses the received amounts of power to produce the directivity information and transmits the directivity information from the primary antenna to
each of the battery monitors, and each of the battery monitors stores the directivity information, as received by a corresponding one of the secondary antennas, in a corresponding one of the secondary storage devices.

### Sixth Structure

The battery monitoring system as set forth in second structure, wherein the battery controller includes a primary storage device (44) which stores therein directivity information representing a linkage between each of channels usable for radio communication between the primary antenna and a corresponding one of the secondary antennas and one of the directivities which causes the received amount of power to be higher than or equal to the given threshold on a corresponding one of the channels, and wherein
the battery controller uses the directivity information retained in the primary storage device to determine one of the directivities which is linked with one of the channels which is used in the radio communication as the first antenna directivity of the primary antenna.

### Seventh Structure

The battery monitoring system as set forth in the sixth structure, wherein when a specific condition is determined to be met, the battery controller outputs an instruction signal from the primary antenna to each of the battery monitors to instruct a corresponding one of the battery monitors to transmit a radio signal from a corresponding one of the secondary antennas,
in response to receiving the instruction signal, each of the battery monitors works to transmit the radio signal from a corresponding one of the secondary antennas to the battery controller,
the battery controller sets the primary antenna to have each of the directivities and receives the radio signal, as outputted from each of the battery monitors, using the primary antenna for each of the directivities, the battery controller measuring amounts of power of the radio signals received by the primary antenna on each of the channels, and
the battery controller uses the measured amounts of power to produce the directivity information and stores the directivity information in the primary storage device.

### Eighth Structure

The battery monitoring system as set forth in the fifth or seventh structure, wherein the specific condition is a condition where in a production process of the battery monitoring system or when the batteries of the battery monitoring system are reused, the batteries, the battery monitors, and the battery controller are disposed in the storage chamber, after which the battery monitoring system is first activated.

### Ninth Structure

The battery monitoring system as set forth in the fifth or seventh structure, wherein the battery monitoring system is mounted in a mobile object (10) in which a user is present, and
the specific condition is a condition where a travel distance or a travel time of the mobile object is determined to exceed a reference threshold (Lth).

### Tenth Structure

The battery monitoring system as set forth in the fifth or seventh structure, wherein the specific condition is a condition where a layout of the batteries, the battery monitors, and the battery controller within the storage chamber is changed from a given one.

### Eleventh Structure

The battery monitoring system as set forth in the tenth structure, wherein the battery monitoring system is mounted in a mobile object (10) in which a user gets, and
when the user provides no instruction to start the mobile object, the mobile object is determined to be stopped, and the specific condition is determined to be met, the battery controller outputs the instruction signal from the primary antenna to each of the battery monitors.

### Twelfth Structure

The battery monitoring system as set forth in the fifth or seventh structure, further comprising an inspection device (300) which is communicably connected to the battery monitors, and
the specific condition is a condition where a request for transmitting information about records of state of the batteries supervised by each of the battery monitors is made by the inspection device.

### Thirteenth Structure

The battery monitoring system as set forth in any one of the first to seventh structures, wherein each of the secondary antennas and/or the primary antenna which is configured to selectively have the first antenna directivity includes a circuit substrate (61), an antenna element (67) mounted on the circuit substrate, a plurality of feeders (68a to 68D, 74A to 74D), and a plurality of ground patterns (69A to 69C, 72, 75),
the feeders are arranged on the circuit substrate and electrically connected to the antenna element to deliver electrical power to the antenna element,
each of the ground patterns is arranged between a respective adjacent two of the feeders on the circuit substrate.

### Fourteenth Structure

The battery monitoring system as set forth in the first structure, wherein on the channel used for the radio communication between the primary antenna and each of the secondary antennas, one of the directivities which causes a communication error rate in the radio communication to be lower than or equal to a given error rate threshold (Eth) is selected as the first antenna directivity.

### Fifteenth Structure

The battery monitoring system as set forth in the first structure, wherein on the channel used for the radio communication between the primary antenna and each of the secondary antennas, one of the directivities which causes a difference between the amount of power received by the battery controller and a noise floor created in the radio communication to be higher than or equal to a given power-to-noise difference threshold (Wth) is selected as the first antenna directivity.

### Sixteenth Structure

A battery controller (40) which is used with a battery monitoring system including a plurality of batteries (21, 21A to 21D, 200), the battery controller, and battery monitors (30, 30A to 30D). The batteries and the battery monitors are disposed in a storage chamber (55, 105) which has at least a portion configured to reflect a radio wave thereon. The battery monitors are provided one for each of the batteries to monitor states of the batteries. Each of the battery monitors is equipped with a secondary antenna (33) used in radio communication between itself and the battery controller. Each of the secondary antenna is configured to selectively have a first antenna directivity that is one of a plurality of directivities whose center axes are different in orientation from each other. The first antenna directivity excludes one of the directivities which causes a degree of quality of radio communication between a primary antenna (43) of the battery controller and a corresponding one of the secondary antennas to be minimized or the lowest among the directivities on a channel used for the radio communication.

### Seventeenth Structure

A battery controller which is used with a battery monitoring system equipped with a plurality of battery monitors (30, 30A to 30D) which are provided one for each of a plurality of batteries (21, 21A to 21D, 200) and work to monitor states of the batteries, comprises:
the batteries, the battery monitors, and the battery controller are disposed in a storage chamber (55, 105) which has at least a portion configured to reflect a radio wave thereon,
the battery controller includes a primary antenna (43) used in radio communication between itself and each of the battery monitors,
the primary antenna is configured to selectively have a first antenna directivity that is one of a plurality of directivities whose center axes are different in orientation from each other, and
the first antenna directivity excludes one of the directivities which causes a degree of quality of radio communication between the primary antenna and a corresponding one of secondary antennas (33) of the battery monitors to be minimized or the lowest among the directivities on a channel used for the radio communication.

This disclosure is not limited to the above embodiments, but may be realized by various embodiments without departing from the purpose of the disclosure. This disclosure includes all possible combinations of the features of the above embodiments or features similar to the parts of the above embodiments. The structures in this disclosure may include only one or some of the features discussed in the above embodiments unless otherwise inconsistent with the aspects of this disclosure.

1. A battery monitoring system comprising:
battery monitors which are provided one for each of a plurality of batteries and work to monitor states of the batteries;
a battery controller; and
a storage chamber which has at least a portion configured to reflect a radio wave thereon and in which the batteries, the battery monitors, and the battery controller are arranged, wherein
the battery controller includes a primary antenna used in radio communications with the battery monitors,
each of the battery monitors includes a secondary antenna used in radio communication with the battery controller,
each of the secondary antennas and/or the primary antenna is configured to selectively have a first antenna directivity that is one of a plurality of directivities whose center axes are different in orientation from each other, and
the first antenna directivity excludes one of the directivities which causes a degree of quality of radio communication between the primary antenna and a corresponding one of the secondary antennas to be lowest among the directivities on a channel used for the radio communication.

2. The battery monitoring system as set forth in claim 1, wherein on the channel used for the radio communication between the primary antenna and each of the secondary antennas, one of the directivities which causes an amount of power received by the battery controller or a corresponding one of the battery monitors to be higher than or equal to a given threshold is selected as the first antenna directivity.

3. The battery monitoring system as set forth in claim 2, wherein on the channel used for the radio communication between the primary antenna and each of the secondary antennas, one of the directivities which causes the received amount of power to be maximized and higher than or equal to the given threshold selected as the first antenna directivity.

4. The battery monitoring system as set forth in claim 2, wherein each of the battery monitors includes a secondary storage device stores therein directivity information representing a linkage between each of channels usable for radio communication between a corresponding one of the secondary antennas and the primary antenna and one of the directivities which causes the received amount of power to be higher than or equal to the given threshold on a corresponding one of the channels, and wherein
each of the battery monitors uses the directivity information retained in the secondary storage device to determine one of the directivities which is linked with one of the channels which is used in the radio communication as the first antenna directivity of a corresponding one of the secondary antennas.

5. The battery monitoring system as set forth in claim 4, wherein when a specific condition is determined to be met, the battery controller outputs an instruction signal from the primary antenna to each of the battery monitors to instruct a corresponding one of the battery monitors to transmit a radio signal from a corresponding one of the secondary antennas for each of the directivities,
when receiving the instruction signal, each of the battery monitors works to transmit the radio signal from a corresponding one of the secondary antennas to the battery controller,
the battery controller receives the radio signal, as transmitted from each of the battery monitors for each of the directivities, using the primary antenna and measures an amount of power of the radio signal received by the primary antenna on each of the channels,
the battery controller uses the received amounts of power to produce the directivity information and transmits the directivity information from the primary antenna to each of the battery monitors, and
each of the battery monitors stores the directivity information, as received by a corresponding one of the secondary antennas, in a corresponding one of the secondary storage devices.

6. The battery monitoring system as set forth in claim 2, wherein the battery controller includes a primary storage device which stores therein directivity information representing a linkage between each of channels usable for radio communication between the primary antenna and a corresponding one of the secondary antennas and one of the directivities which causes the received amount of power to be higher than or equal to the given threshold on a corresponding one of the channels, and wherein
the battery controller uses the directivity information retained in the primary storage device to determine one of the directivities which is linked with one of the channels which is used in the radio communication as the first antenna directivity of the primary antenna.

7. The battery monitoring system as set forth in claim 6, wherein when a specific condition is determined to be met, the battery controller outputs an instruction signal from the primary antenna to each of the battery monitors to instruct a corresponding one of the battery monitors to transmit a radio signal from a corresponding one of the secondary antennas,
when receiving the instruction signal, each of the battery monitors works to transmit the radio signal from a corresponding one of the secondary antennas to the battery controller,
the battery controller sets the primary antenna to have each of the directivities and receives the radio signal, as outputted from each of the battery monitors, using the primary antenna for each of the directivities, the battery controller measuring amounts of power of the radio signals received by the primary antenna on each of the channels, and
the battery controller uses the measured amounts of power to produce the directivity information and stores the directivity information in the primary storage device.

8. The battery monitoring system as set forth in claim 5, wherein the specific condition is a condition where in a production process of the battery monitoring system or when the batteries of the battery monitoring system are reused, the batteries, the battery monitors, and the battery controller are disposed in the storage chamber, after which the battery monitoring system is first activated.

9. The battery monitoring system as set forth in claim 5, wherein the battery monitoring system is mounted in a mobile object in which a user gets, and
the specific condition is a condition where a travel distance or a travel time of the mobile object is determined to exceed a reference threshold.

10. The battery monitoring system as set forth in claim 5, wherein the specific condition is a condition where a layout of the batteries, the battery monitors, and the battery controller within the storage chamber is changed from a given one.

11. The battery monitoring system as set forth in claim 10, wherein the battery monitoring system is mounted in a mobile object in which a user gets, and
when the user provides no instruction to start the mobile object, the mobile object is determined to be stopped, and the specific condition is determined to be met, the battery controller outputs the instruction signal from the primary antenna to each of the battery monitors.

12. The battery monitoring system as set forth in claim 5, further comprising an inspection device which is communicably connected to the battery monitors, and
the specific condition is a condition where a request for transmitting information about records of state of the batteries supervised by each of the battery monitors is made by the inspection device.

13. The battery monitoring system as set forth in claim 1, wherein each of the secondary antennas and/or the primary antenna which is configured to selectively have the first antenna directivity includes a circuit, substrate, an antenna element mounted on the circuit substrate, a plurality of feeders, and a plurality of ground patterns patterns,
the feeders are arranged on the circuit substrate and electrically connected to the antenna element to deliver electrical power to the antenna element,
each of the ground patterns is arranged between a respective adjacent two of the feeders on the circuit substrate.

14. The battery monitoring system as set forth in claim 1, wherein on the channel used for the radio communication between the primary antenna and each of the secondary antennas, one of the directivities which causes a communication error rate in the radio communication to be lower than or equal to a given error rate threshold is selected as the first antenna directivity.

15. The battery monitoring system as set forth in claim 1, wherein on the channel used for the radio communication between the primary antenna and each of the secondary antennas, one of the directivities which causes a difference between the amount of power received by the battery controller and a noise floor created in the radio communication to be higher than or equal to a given power-to-noise difference threshold is selected as the first antenna directivity.

16. A battery controller which is used with a battery monitoring system including a plurality of batteries, the battery controller, and battery monitors,
the batteries and the battery monitors are disposed in a storage chamber which has at least a portion configured to reflect a radio wave thereon,
the battery monitors are provided one for each of the batteries to monitor states of the batteries,
each of the battery monitors is equipped with a secondary antenna used in radio communication between itself and the battery controller,
each of the secondary antenna is configured to selectively have a first antenna directivity that is one of a plurality of directivities whose center axes are different in orientation from each other, and
the first antenna directivity excludes one of the directivities which causes a degree of quality of radio communication between a primary antenna of the battery controller and a corresponding one of the secondary antennas to be lowest among the directivities on a channel used for the radio communication.

17. A battery controller which is used with a battery monitoring system equipped with a plurality of battery monitors which are provided one for each of a plurality of batteries and work to monitor states of the batteries, comprising:
the batteries, the battery monitors, and the battery controller are disposed in a storage chamber which has at least a portion configured to reflect a radio wave thereon,
the battery controller includes a primary antenna used in radio communication between itself and each of the battery monitors,
the primary antenna is configured to selectively have a first antenna directivity that is one of a plurality of directivities whose center axes are different in orientation from each other, and
the first antenna directivity excludes one of the directivities which causes a degree of quality of radio communication between the primary antenna and a corresponding one of secondary antennas of the battery monitors to be lowest among the directivities on a channel used for the radio communication.
